(19) United States
(12) Patent Application Publication
(10) Pub. No.: US 2023/0225203 A1
(43) Pub. Date: Jul. 13, 2023

(54) ORGANIC LUMINESCENT ELEMENT

(71) Applicant: KYULUX, INC., Fukuoka-shi, Fukuoka (JP)

(72) Inventor: Hayato KAKIZOE, Fukuoka-shi, Fukuoka (JP)

(21) Appl. No.: 18/004,391

(22) PCT Filed: Jul. 2, 2021
(86) PCT No.: PCT/JP2021/025071

§ 371 Date: Jan. 5, 2023

(30) Foreign Application Priority Data
Jul. 6, 2020 (JP) 2020-116526
Mar. 1, 2021 (JP) 2021-031436

(51) Int. Cl. H10K 85/60; H10K 50/11

(52) U.S. Cl. CPC H10K 85/6572; H10K 50/11; H10K 85/654; H10K 85/6574; H10K 85/6576; H10K 85/658; H10K 85/636; H10K 85/624; H10K 85/622; H10K 85/623; H10K 85/633; H10K 85/615; H10K 85/626; H10K 2101/20

(57) ABSTRACT

An organic light emitting device having a light emitting layer that contains first to fourth organic compounds satisfying the following formulae has a long emission lifetime and is stable. The second organic compound is a delayed fluorescent material, and the amount of light emission from the fourth organic compound is the maximum. E_{S1} is a lowest excited singlet energy, E_{T1} is a lowest excited triplet energy. E_{S1}(1)>E_{S1}(4)>E_{S1}(2)>E_{S1}(3), E_{T1}(1)>E_{T1}(2)>E_{T1}(3)>E_{T1}(4).

### TECHNICAL FIELD

The present invention relates to an organic light emitting device using a delayed fluorescent material.

### BACKGROUND ART

Studies for enhancing the light emission efficiency of organic light-emitting devices such as organic electroluminescent devices (organic EL devices) are being made actively. In particular, various kinds of efforts have been made for increasing light emission efficiency by newly developing and combining an electron transporting material, a hole transporting material, a host material and a light emitting material to constitute an organic electroluminescent device. Among them, there are seen studies relating to an organic light emitting device that utilizes a delayed fluorescent material.

A delayed fluorescent material is a material which, in an excited state, after having undergone reverse intersystem crossing from an excited triplet state to an excited singlet state, emits fluorescence when returning back from the excited singlet state to a ground state thereof. Fluorescence through the route is observed later than fluorescence from the excited singlet state directly occurring from the ground state (ordinary fluorescence), and is therefore referred to as delayed fluorescence. Here, for example, in the case where a light-emitting compound is excited through carrier injection thereinto, the occurring probability of the excited singlet state to the excited triplet state is statistically 25%/75%, and therefore improvement of light emission efficiency by the fluorescence alone from the directly occurring excited singlet state is limited. On the other hand, in a delayed fluorescent material, not only the excited singlet state thereof but also the excited triplet state can be utilized for fluorescent emission through the route via the above-mentioned reverse intersystem crossing, and therefore as compared with an ordinary fluorescent material, a delayed fluorescent material can realize a higher emission efficiency.

As such a delayed fluorescent material, there has been proposed a benzene derivative having a heteroaryl group such as a carbazolyl group or a diphenylamino group, and at least two cyano groups, and it has been confirmed that an organic EL device using the benzene derivative in a light emitting layer provides a high emission efficiency (see PTL 1).

Also, NPL 1 reports that a carbazolyldicyanobenzene derivative (4CzTPN) is a thermally activated delayed fluorescent material and that an organic electroluminescent device using the carbazolyldicyanobenzene derivative attained a high internal EL quantum efficiency.

On the other hand, using a delayed fluorescent material in a light emitting layer as an assist dopant but not as a light emitting material therein has been reported (see PTL 2). This describes adding, in addition to a host material and a fluorescent material, a delayed fluorescent material having an intermediate lowest excited singlet energy between the host material and the fluorescent light emitting material to the light emitting layer to improve emission efficiency.

### CITATION LIST

### Patent Literature

PTL 1: JP2014-43541A
PTL 2: JP2015-179809A

### Non-Patent Literature

NPL 1: H. Uoyama, et al., Nature 492, 234 (2012)

### SUMMARY OF INVENTION

### Technical Problem

As described above, PTL 1, PTL 2 and NPL 1 report that an organic electroluminescent device using a delayed fluorescent material attained a high emission efficiency. However, when the present inventors produced organic electroluminescent devices according to the descriptions of PTL 1 and PTL 2, it was found that it was not easy to secure a sufficient lifetime.

Given the situations, the present inventors have promoted assiduous studies for the purpose of improving the lifetime of an organic light emitting device using a delayed fluorescent material.

### Solution to Problem

As a result of further promoting assiduous studies for attaining the above-mentioned object, the present inventors have found that, by adding a host material, a delayed fluorescent material, a light emitting material and a modifier satisfying specific requirements to a light emitting layer, an organic light emitting device having a long emission lifetime and stable can be realized. The present invention has been proposed on the basis of such findings, and specifically has the following constitution.

[1] An organic light emitting device having a light emitting layer that contains a first organic compound, a second organic compound, a third organic compound and a fourth organic compound satisfying the following requirements (a) and (b), wherein:

the second organic compound is a delayed fluorescent material,

the maximum component of light emission from the organic light emitting device is light emission from the third organic compound:

Requirement (a): E_{S1}(1)>E_{S1}(4)>E_{S1}(2)>E_{S1}(3)

Requirement (b): E_{T1}(1)>E_{T1}(2)>E_{T1}(3)>E_{T1}(4)

wherein:

E_{S1}(1) represents a lowest excited singlet energy of the first organic compound,

E_{S1}(2) represents a lowest excited singlet energy of the second organic compound.

E_{S1}(3) represents a lowest excited singlet energy of the third organic compound,

E_{S1}(4) represents a lowest excited singlet energy of the fourth organic compound,

E_{T1}(1) represents a lowest excited triplet energy of the first organic compound,

E_{T1}(2) represents a lowest excited triplet energy of the second organic compound.

E_{T1}(3) represents a lowest excited triplet energy of the third organic compound,

E_{T1}(4) represents a lowest excited triplet energy of the fourth organic compound.

[2] The organic light emitting device according to [1], further satisfying the following requirement (c):

Requirement (c): Conc(1)>Conc(2)>Conc(4)

wherein:

Conc(1) represents a concentration of the first organic compound in the light emitting layer,

Conc(2) represents a concentration of the second organic compound in the light emitting layer,

Conc(4) represents a concentration of the fourth organic compound in the light emitting layer.

[3] The organic light emitting device according to [2], further satisfying the following requirement (c1):

Requirement (c1): Conc(1)>Conc(2)>Conc(4)>Conc(3)

wherein:

Conc(3) represents a concentration of the third organic compound in the light emitting layer.

[4] The organic light emitting device according to [2] or [3], further satisfying the following requirement (d):

Requirement (d): Conc(2)/Conc(3)>5

wherein:

Conc(3) represents a concentration of the third organic compound in the light emitting layer.

[5] The organic light emitting device according to any one of [2] to [4], further satisfying the following requirement (e):

Requirement (e): Conc(4)/Conc(3)>1.5 wherein:

Conc(3) represents a concentration of the third organic compound in the light emitting layer.

[6] The organic light emitting device according to any one of [1] to [5] further satisfying the following requirement (f):

Requirement (f): Conc(4)<5 wt %

wherein:

Conc(4) represents a concentration of the fourth organic compound in the light emitting layer.

[7] The organic light emitting device according to any one of [1] to [6], further satisfying the following requirement (g):

Requirement (g): Conc(3)≤1 wt %

wherein:

Conc(3) represents a concentration of the third organic compound in the light emitting layer.

[8] The organic light emitting device according to any one of [1] to [7], wherein the second organic compound is such that an energy difference ΔEₛₜ between a lowest excited single state and a lowest excited triplet state at 77 K is 0.3 eV or less.

[9] The organic light emitting device according to any one of [1] to [8], wherein the third organic compound is such that the energy difference ΔEₛₜ between a lowest excited single state and a lowest excited triplet state at 77 K is 0.3 eV or less.

[10] The organic light emitting device according to any one of [1] to [9], wherein the light emitting layer is composed of a compound alone formed of atoms selected from the group consisting of a carbon atom, a hydrogen atom, a nitrogen atom, a boron atom, an oxygen atom and a sulfur atom.

[11] The organic light emitting device according to any one of [1] to [10], wherein the first organic compound, the second organic compound and the fourth organic compound each are independently a compound formed of atoms selected from the group consisting of a carbon atom, a hydrogen atom and a nitrogen atom.

[12] The organic light emitting device according to any one of [1] to [11], wherein the fourth organic compound is a compound composed of only a carbon atom and a hydrogen atom.

[13] The organic light emitting device according to any one of [1] to [12], wherein the second organic compound contains a cyanobenzene structure.

[14] A method for designing a light emitting composition, including the following steps:

[Step 1] evaluating an emission efficiency and a lifetime of a composition containing a first organic compound, a second organic compound of a delayed fluorescent material, a third organic compound and a fourth organic compound and satisfying the following requirements (a) and (b),

[Step 2] carrying out at least once evaluating an emission efficiency and a lifetime of a composition in which at least one of the first organic compound, the second organic compound of a delayed fluorescent material, the third organic compound and the fourth organic compound has been replaced within a range satisfying the following requirements (a) and (b),

[Step 3] selecting a best combination of the results of the evaluated emission efficiency and lifetime:

Requirement (a): E_{S1}(1)>E_{S1}(4)>E_{S1}(2)>E_{S1}(3)

Requirement (b): E_{T1}(1)>E_{T1}(2)>E_{T1}(3)>E_{T1}(4)

wherein:

E_{S1}(1) represents a lowest excited singlet energy of the first organic compound.

E_{S1}(2) represents a lowest excited singlet energy of the second organic compound,

E_{S1}(3) represents a lowest excited singlet energy of the third organic compound,

E_{S1}(4) represents a lowest excited singlet energy of the fourth organic compound,

E_{T1}(1) represents a lowest excited triplet energy of the first organic compound,

E_{T1}(2) represents a lowest excited triplet energy of the second organic compound,

E_{T1}(3) represents a lowest excited triplet energy of the third organic compound,

E_{T1}(4) represents a lowest excited triplet energy of the fourth organic compound.

A program of carrying out the method of [14].

### Advantageous Effects of Invention

The organic light emitting device of the present invention can realize long-life light emission.

### BRIEF DESCRIPTION OF DRAWINGS

FIG. 1 This is a schematic cross-sectional view showing a layer configuration example of an organic electroluminescent device.

### DESCRIPTION OF EMBODIMENTS

The contents of the invention will be described in detail below. The constitutional elements may be described below with reference to representative embodiments and specific examples of the invention, but the invention is not limited to the embodiments and the examples. In the description herein, a numerical range expressed as “to” means a range that includes the numerical values described before and after “to” as the upper limit and the lower limit. In the description, “XXX is composed of” means that XXX is formed of only those described after “composed of” and does not contain any others. The hydrogen atom that is present in the molecule of the compound used in the invention is not particularly limited in isotope species, and for example, all the hydrogen atoms in the molecule may be ¹H, and all or a part of them may be ²H (deuterium D).

### (Characteristics of Organic Light Emitting Device)

The organic light emitting device of the present invention has a light emitting layer that contains a first organic compound, a second organic compound, a third organic compound and a fourth organic compound. Among these, the second organic compound is a delayed fluorescent material. With that, the organic compounds satisfy the following requirements (a) and (b):

Requirement (a): E_{S1}(1)>E_{S1}(4)>E_{S1}(2)>E_{S1}(3)

Requirement (b): E_{T1}(1)>E_{T1}(2)>E_{T1}(3)>E_{T1}(4)

In the present invention, E_{S1}(1) represents a lowest excited singlet energy of the first organic compound, E_{S1}(2) represents a lowest excited singlet energy of the second organic compound, E_{S1}(3) represents a lowest excited singlet energy of the third organic compound, E_{S1}(4) represents a lowest excited singlet energy of the fourth organic compound. In the present invention, eV is employed as the unit.

E_{T1}(1) represents a lowest excited triplet energy of the first organic compound, E_{T1}(2) represents a lowest excited triplet energy of the second organic compound, E_{T1}(3) represents a lowest excited triplet energy of the third organic compound, E_{T1}(4) represents a lowest excited triplet energy of the fourth organic compound. In the present invention, eV is employed as the unit.

Conc(1) represents a concentration of the first organic compound in the light emitting layer, Conc(2) represents a concentration of the second organic compound in the light emitting layer, Conc(3) represents a concentration of the third organic compound in the light emitting layer, Conc(4) represents a concentration of the fourth organic compound in the light emitting layer. In the present invention, wt % is employed as the unit.

The organic light emitting device of the present invention satisfies the requirements (a) (b) at the same time for the lowest excited singlet energy. Therefore, the lowest excited singlet energy E_{S1}(2) and the lowest excited triplet energy E_{T1}(2) of the second organic compound, and the lowest excited singlet energy E_{S1}(3) and the lowest excited triplet energy E_{S1}(3) of the third organic compound each are between the lowest excited singlet energy E_{S1}(4) and the lowest excited triplet energy E_{T1}(4) of the fourth organic compound. Consequently, of the fourth organic compound, the difference ΔE_{ST}(4) between the lowest excited single energy and the lowest excited triplet energy at 77 K is larger than that of the second organic compound and the third organic compound. ΔE_{ST}(4) of the fourth organic compound is preferably 0.5 eV or more, more preferably 0.6 eV or more, even more preferably 0.7 eV or more. ΔE_{ST}(4) of the fourth organic compound can be, for example, within a range of 1.5 eV or less, or can be within a range of 1.2 eV or less, or can be within a range of 0.9 eV or less.

The difference in the lowest excited singlet energy between the fourth organic compound and the second compound E_{S1}(4)-E_{S1}(2) is preferably 0.05 eV or more, more preferably 0.10 eV or more, and can be 0.15 eV or more. E_{S1}(4)-E_{S1}(2) can be, for example, within a range of 0.7 eV or less, or can be within a range of 0.5 eV or less, or can be within a range of 0.3 eV or less.

The difference in the lowest excited triplet energy between the third organic compound and the fourth compound E_{T1}(3)-E_{T1}(4) is preferably 0.10 eV or more, more preferably 0.30 eV or more, and can be 0.45 eV or more. E_{T1}(3)-E_{T1}(4) can be, for example, within a range of 0.9 eV or less, or can be within a range of 0.7 eV or less, or can be within a range of 0.5 eV or less.

The difference in the lowest excited singlet energy between the first organic compound and the second compound E_{S1}(1)-E_{S1}(2) can be within a range of 0.3 eV or more, or can be within a range of 0.5 eV or more, or can be within a range of 0.7 eV or more, and can also be within a range of 1.6 eV or less, or can be within a range of 1.3 eV or less, or can be within a range of 0.9 eV or less.

The difference in the lowest excited singlet energy between the first organic compound and the fourth compound E_{S1}(1)-E_{S1}(4) can be within a range of 0.2 eV or more, or can be within a range of 0.4 eV or more, or can be within a range of 0.6 eV or more, and can also be within a range of 1.5 eV or less, or can be within a range of 1.2 eV or less, or can be within a range of 0.8 eV or less.

The lowest excited triplet energy E_{T1}(1) of the first organic compound can be larger than the lowest excited singlet energy E_{S1}(4) of the fourth compound. For example, E_{T1}(1)-E_{S1}(4) can be within a range of 0.05 eV or more, or can be within a range of 0.10 eV or more, or can be within a range of 0.15 eV or more. Also it can be within a range of 0.7 eV or less, or can be within a range of 0.5 eV or less, or can be within a range of 0.3 eV or less.

Preferably, the organic light emitting device of the present invention satisfies the requirement (c) for the content of the first compound, the second compound and the fourth compound therein.

Requirement (c): Conc(1)>Conc(2)>Conc(4)

Preferably, the organic light emitting device of the present invention satisfies the requirement (c1) for the content of the first to fourth compounds therein.

Requirement (c1): Conc(1)>Conc(2)>Conc(4)>Conc(3)

Conc(1) is preferably 30% by weight or more, and can be within a range of 50% by weight or more, or can be within a range of 65% by weight or more, and also can be within a range of 99% by weight or less, or can be within a range of 85% by weight or less, or can be within a range of 75% by weight or less.

Conc(2) is preferably 10% by weight or more, and can be within a range of 20% by weight or more, or can be within a range of 30% by weight or more, and also can be within a range of 45% by weight or less, or can be within a range of 40% by weight or less, or can be within a range of 35% by weight or less.

Conc(3) is preferably 5% by weight or less, more preferably 3% by weight or less. Conc(3) can be within a range of 1% by weight or less, or can be within a range of 0.5% by weight or less, and also can be within a range of 0.01% by weight or more, or can be within a range of 0.1% by weight or more, or can be within a range of 0.3% by weight or more.

Conc(4) is preferably 15% by weight or less, more preferably 10% by weight or less, even more preferably 5% by weight or less. Conc(4) can be within a range of 0.01% by weight or more, or can be within a range of 1% by weight or more, or can be within a range of 3% by weight or more, or can be within a range of 4% by weight or more.

Preferably, the organic light emitting device of the present invention further satisfies the following requirement (d).

Requirement (d): Conc(2)/Conc(3)>5

Conc(2)/Conc(3) can be within a range of 10 or more, or can be within a range of 30 or more, or can be within a range of 50 or more, and also can be within a range of 500 or less, or can be within a range of 300 or less, or can be within a range of 100 or less.

Preferably, the organic light emitting device of the present invention further satisfies the following requirement (e).

Requirement (e): Conc(4)/Conc(3)>1.5

Conc(4)/Conc(3) can be within a range of 2 or more, or can be within a range of or more, or can be within a range of 10 or more, and also can be within a range of 500 or less, or can be within a range of 100 or less, or can be within a range of 50 or less.

The second organic compound used in the organic light emitting device of the present invention is a delayed fluorescent material. “Delayed fluorescent material” in the present invention is an organic compound which, in an excited state, undergoes reverse intersystem crossing from an excited triplet state to an excited singlet state, and which emits fluorescence (delayed fluorescence) in returning back from the excited singlet state to a ground state. In the present invention, a compound which gives fluorescence having an emission lifetime of 100 ns (nanoseconds) or longer, when the emission lifetime is measured with a fluorescence lifetime measuring system (e.g., streak camera system by Hamamatsu Photonics KK), is referred to as a delayed fluorescent material.

The second organic compound is preferably such that the difference ΔE_{ST}(2) between the lowest excited singlet energy and the lowest excited triplet energy at 77K is 0.3 eV or less, more preferably 0.25 eV or less, even more preferably 0.2 eV or less, further more preferably 0.15 eV or less, further more preferably 0.1 eV or less, further more preferably 0.07 eV or less, further more preferably 0.05 eV or less, further more preferably 0.03 eV or less, particularly preferably 0.01 eV or less.

When ΔE_{ST}(2) is smaller, reverse intersystem crossing from an excited triplet state to an excited singlet state can more readily occur through thermal energy absorption, and therefore the second organic compound can function as a thermal activation type delayed fluorescent material. A thermal activation type delayed fluorescent material can absorb heat generated by a device to relatively readily undergo reverse intersystem crossing from an excited triplet state to an excited singlet state, and can make the excited triplet energy efficiently contribute toward light emission.

In the invention, the difference ΔE_{ST} between a lowest excited singlet energy level (E_{S1}) and a lowest excited triplet energy level (Ent) of a compound is determined according to the following process. ΔE_{ST} is a value determined by calculating E_{S1}-E_{T1}.

### (1) Lowest Excited Singlet Energy (E_{S1})

A thin film or a toluene solution (concentration: 10⁻⁵ mol/L) of the targeted compound is prepared as a measurement sample. The fluorescent spectrum of the sample is measured at room temperature (300 K). For the fluorescent spectrum, the emission intensity is on the vertical axis and the wavelength is on the horizontal axis. A tangent line is drawn to the rising of the emission spectrum on the short wavelength side, and the wavelength value λedge [nm] at the intersection between the tangent line and the horizontal axis is read. The wavelength value is converted into an energy value according to the following conversion expression to calculate E_{S1}.

Conversion Expression: E_{S1} [eV]=1239.85/λedge

For the measurement of the emission spectrum in Examples given below, an LED light source (by Thorlabs Corporation, M340L4) was used as an excitation light source along with a detector (by Hamamatsu Photonics K.K., PMA-12 Multichannel Spectroscope C10027-01).

### (2) Lowest Excited Triplet Energy (En)

The same sample as that for measurement of the lowest excited singlet energy (E_{S1}) is cooled to 77 [K] with liquid nitrogen, and the sample for phosphorescence measurement is irradiated with excitation light (300 nm), and using a detector, the phosphorescence thereof is measured. The emission after 100 milliseconds from irradiation with the excitation light is drawn as a phosphorescent spectrum. A tangent line is drawn to the rising of the phosphorescent spectrum on the short wavelength side, and the wavelength value λedge [nm] at the intersection between the tangent line and the horizontal axis is read. The wavelength value is converted into an energy value according to the following conversion expression to calculate E_{T1}.

Conversion Expression: E_{T1} [eV]=1239.85/λedge

The tangent line to the rising of the phosphorescent spectrum on the short wavelength side is drawn as follows. While moving on the spectral curve from the short wavelength side of the phosphorescent spectrum toward the maximum value on the shortest wavelength side among the maximum values of the spectrum, a tangent line at each point on the curve toward the long wavelength side is taken into consideration. With rising thereof (that is, with increase in the vertical axis), the inclination of the tangent line increases. The tangent line drawn at the point at which the inclination value has a maximum value is referred to as the tangent line to the rising on the short wavelength side of the phosphorescent spectrum.

The maximum point having a peak intensity of 10% or less of the maximum peak intensity of the spectrum is not included in the maximum value on the above-mentioned shortest wavelength side, and the tangent line drawn at the point which is closest to the maximum value on the shortest wavelength side and at which the inclination value has a maximum value is referred to as the tangent line to the rising on the short wavelength side of the phosphorescent spectrum.

### (First Organic Compound)

The first organic compound is an organic compound having a larger lowest excited singlet energy than the second organic compound, the third organic compound and the fourth organic compound, and has a function as a host material acting for transporting carriers or has a function of confining the energy of the third organic compound thereto. Accordingly, the third organic compound can efficiently change the energy having formed by recombination of holes and electrons in the molecule and the energy having received from the first organic compound and the second organic compound, for light emission.

The first organic compound is preferably an organic compound having a hole transporting capability and an electron transporting capability, capable of preventing light emission from being in a longer wavelength range and having a high glass transition temperature. In a preferred embodiment of the present invention, the first organic compound is selected from compounds not emitting delayed fluorescence.

Hereinunder shown are preferred compounds usable as the first organic compound.

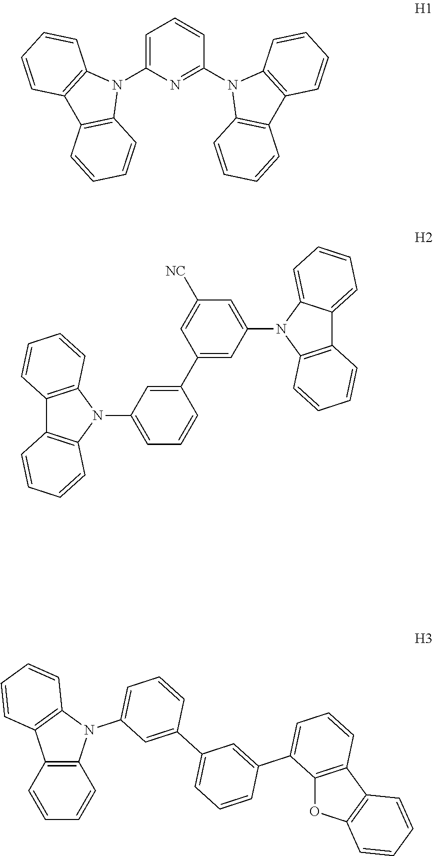 [SMILES: c1cc(-n2c3ccccc3c3ccccc32)nc(-n2c3ccccc3c3ccccc32)c1 ; N#Cc1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1]

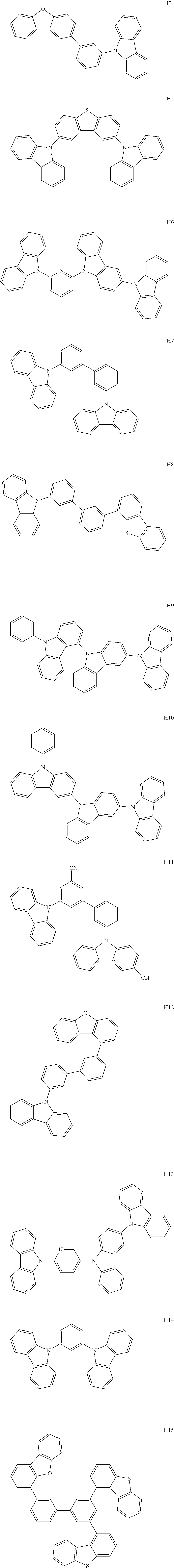

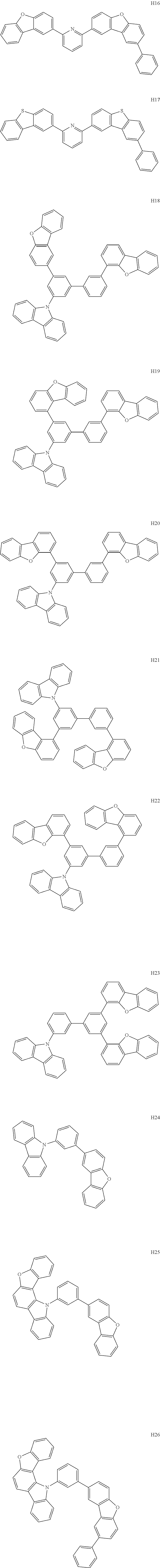

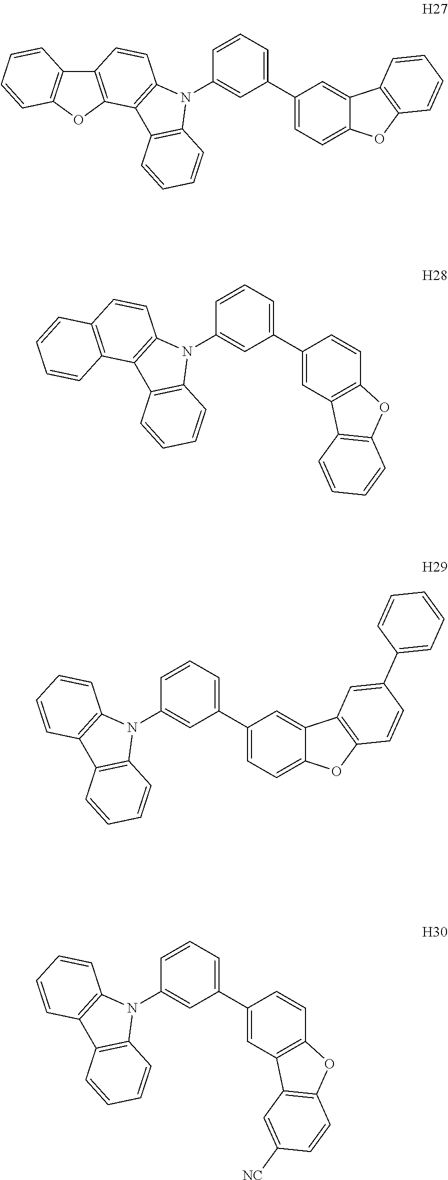 [SMILES: c1cc(-c2ccc3oc4ccccc4c3c2)cc(-n2c3ccccc3c3c4oc5ccccc5c4ccc32)c1 ; c1cc(-c2ccc3oc4ccccc4c3c2)cc(-n2c3ccccc3c3c4ccccc4ccc32)c1 ; c1ccc(-c2ccc3oc4ccc(-c5cccc(-n6c7ccccc7c7ccccc76)c5)cc4c3c2)cc1 ; N#Cc1ccc2oc3ccc(-c4cccc(-n5c6ccccc6c6ccccc65)c4)cc3c2c1]

### (Second Organic Compound)

The second organic compound is a delayed fluorescent material having a smaller lowest excited singlet energy than the first organic compound and the fourth organic compound and having a larger lowest excited singlet energy than the third organic compound. Also the second organic compound is a delayed fluorescent material having a smaller lowest excited triplet energy than the first organic compound and having a larger lowest excited triplet energy than the third organic compound and the fourth organic compound. The second organic compound can be a compound capable of emitting delayed fluorescent under some conditions, and for the organic light emitting device of the present invention, it is not essential to emit delayed fluorescence derived from the second organic compound. In the organic light emitting device of the present invention, the second organic compound receives energy from the first organic compound and the fourth organic compound in an excited singlet state to transition into an excited singlet state. Also the second organic compound can receive energy from the first organic compound in an excited triplet state to transition into an excited triplet state. The second organic compound has a small ΔE_{ST}, and therefore the second organic compound in an excited triplet state can readily undergo reverse intersystem crossing to be the second organic compound in an excited singlet state. The second organic compound in an excited singlet state that has been formed in such routes can give energy to the third organic compound to make the third organic compound transition into an excited singlet state.

Hereinunder shown are preferred compounds that can be used as the second organic compound. In the structural formulae of the exemplified compounds shown below, t-Bu represents a tertiary butyl group.

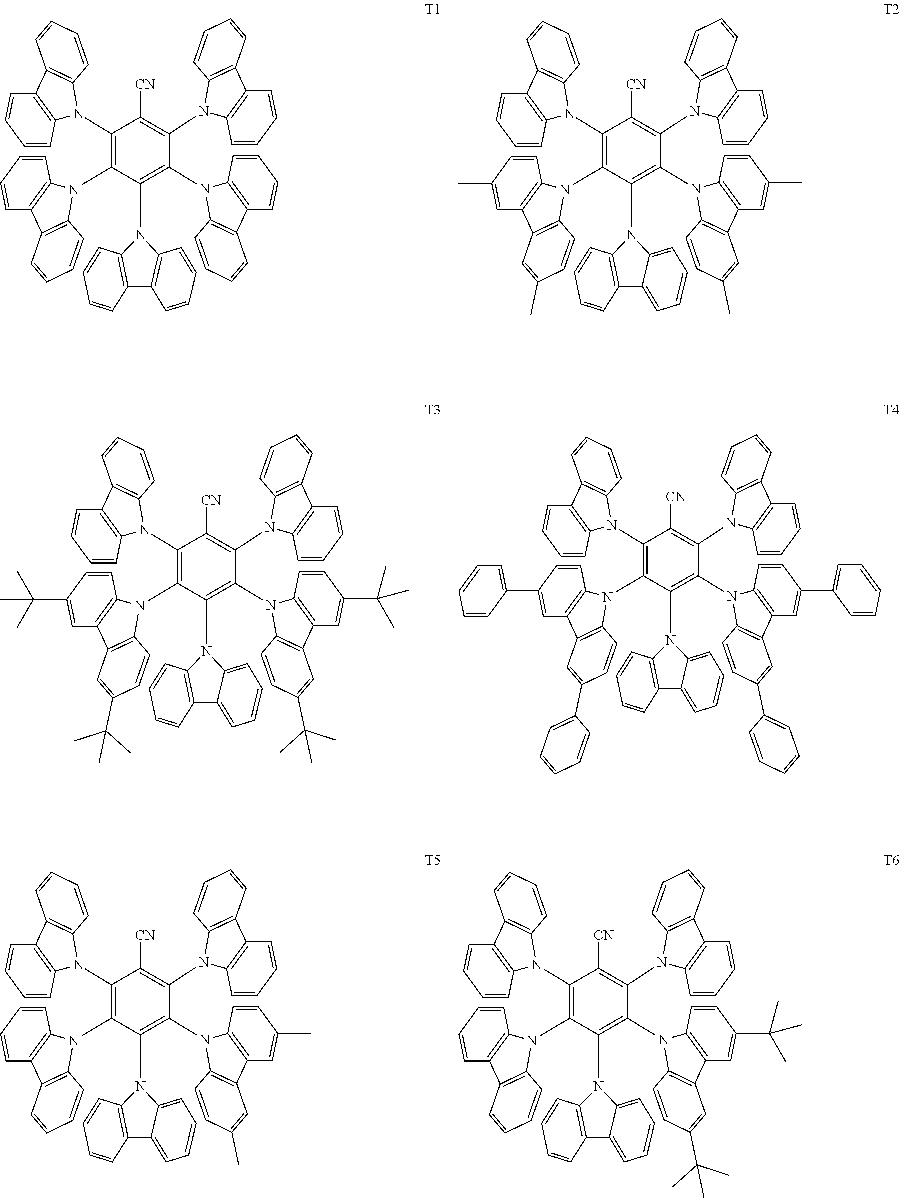

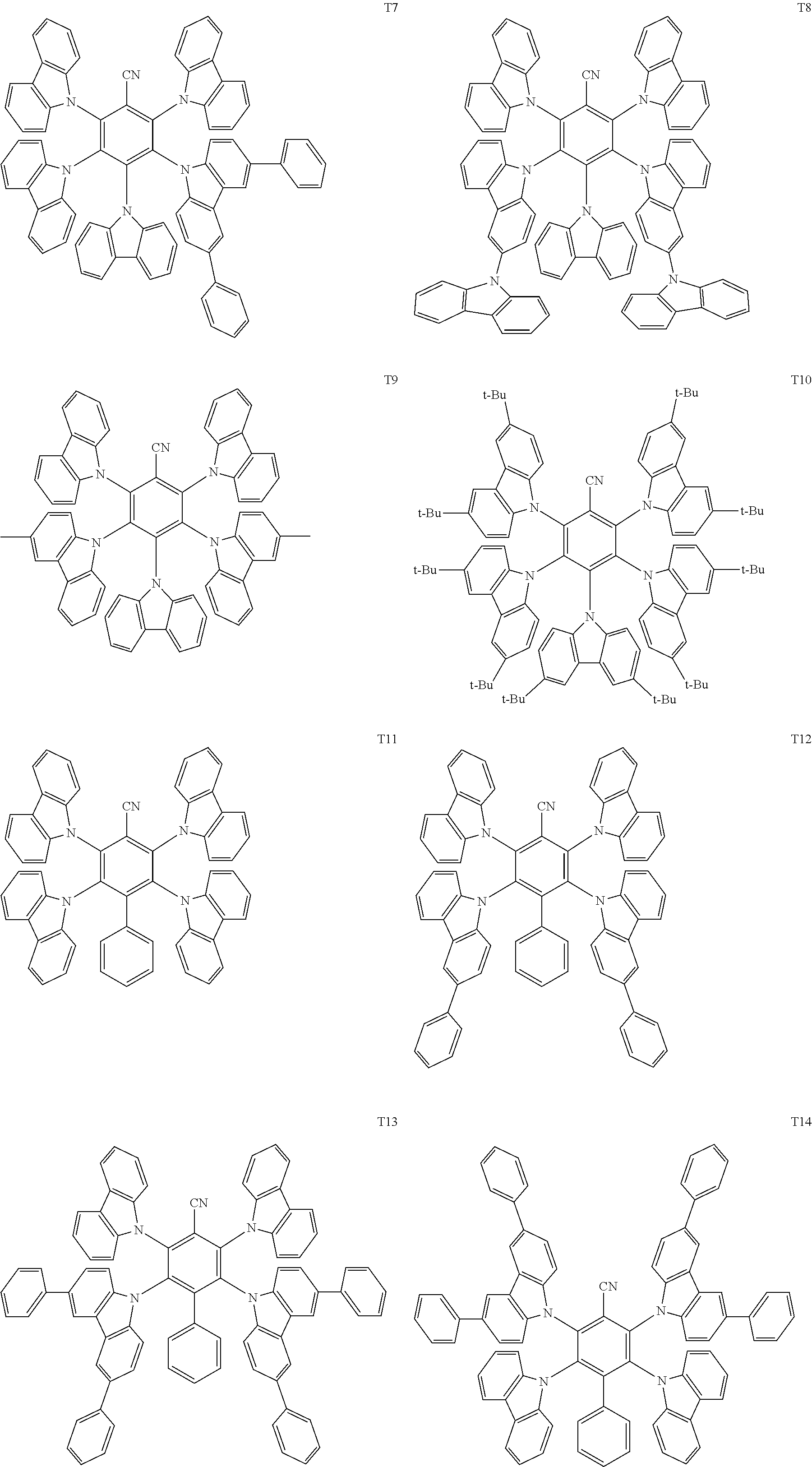

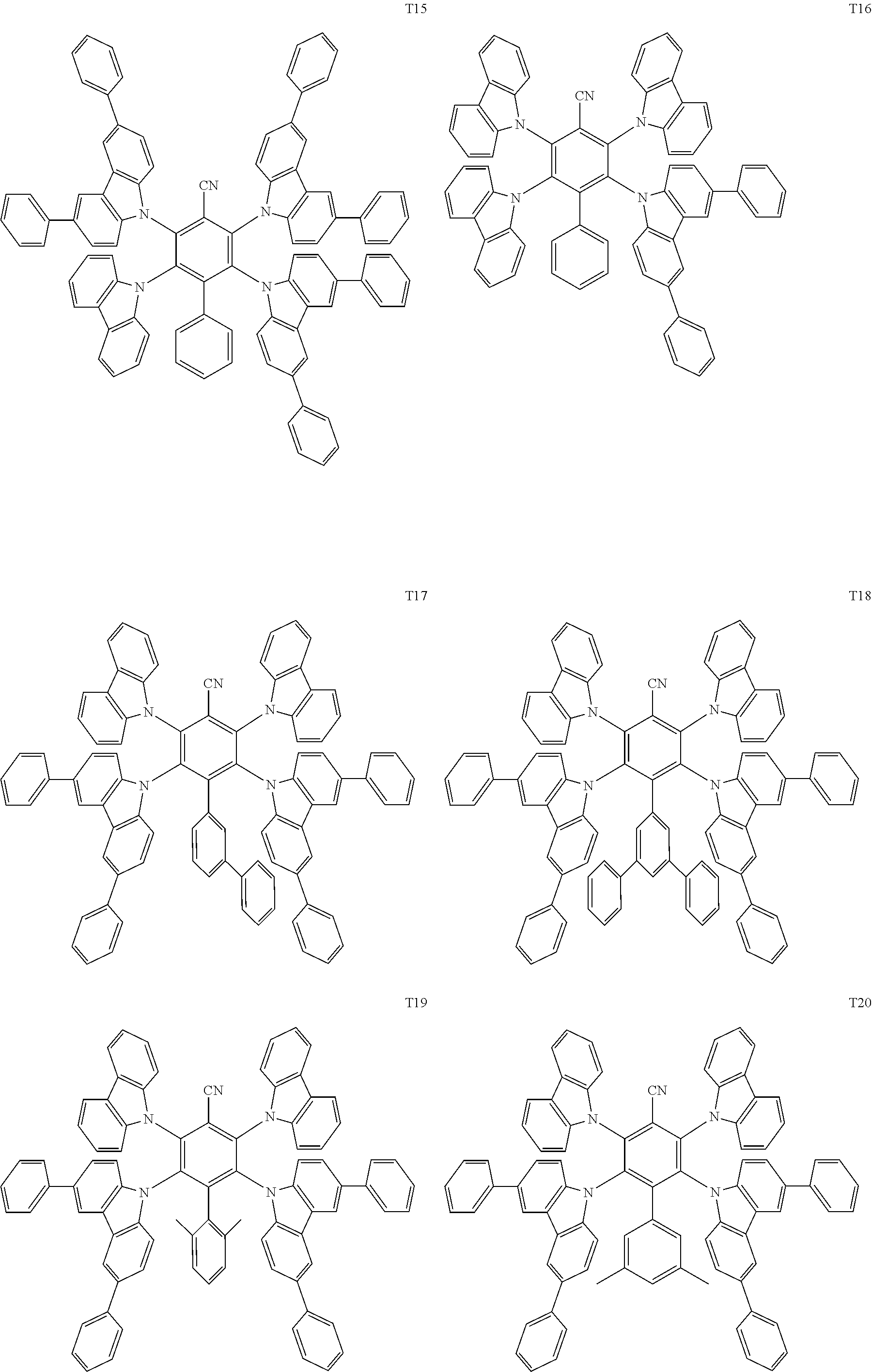

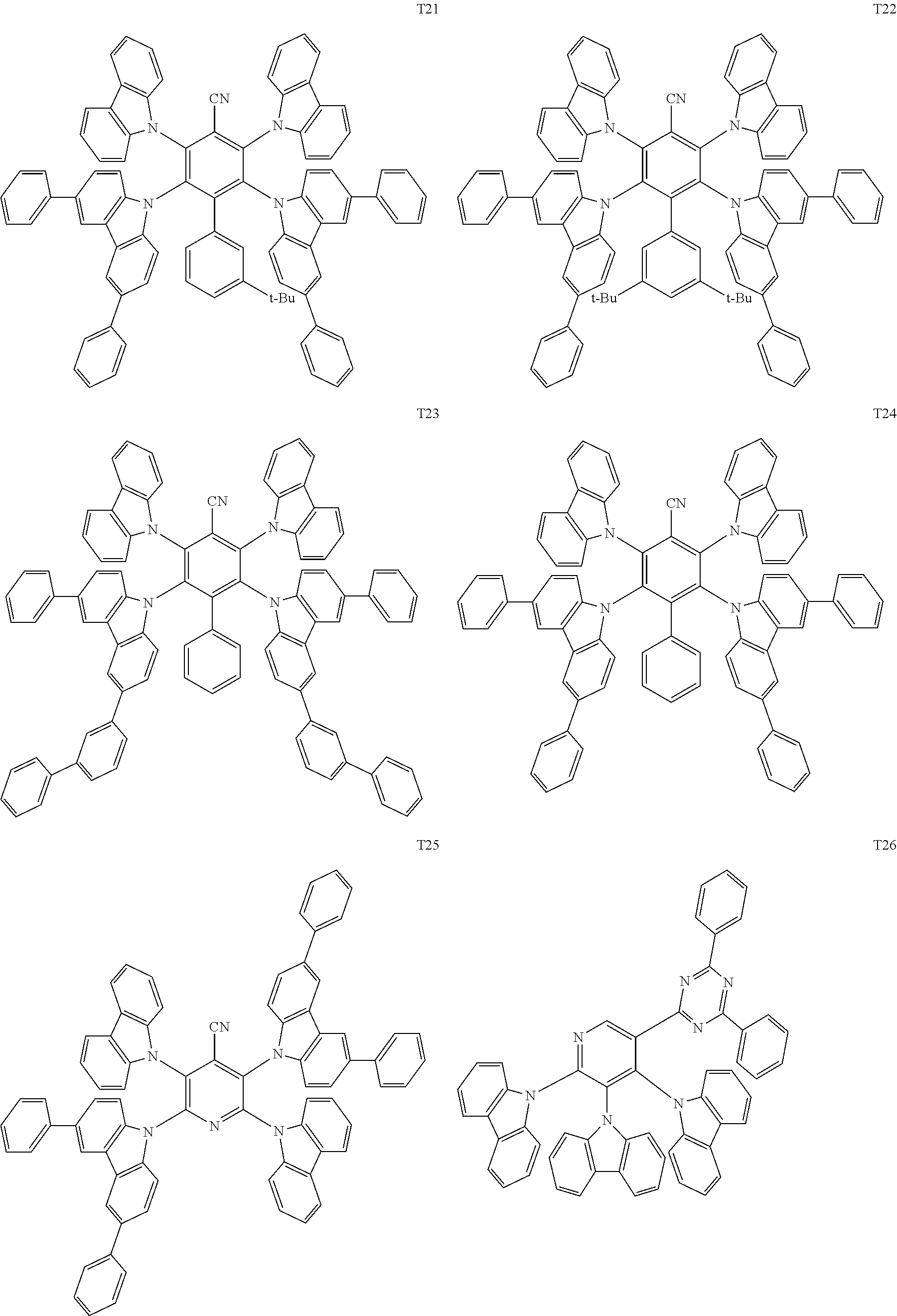

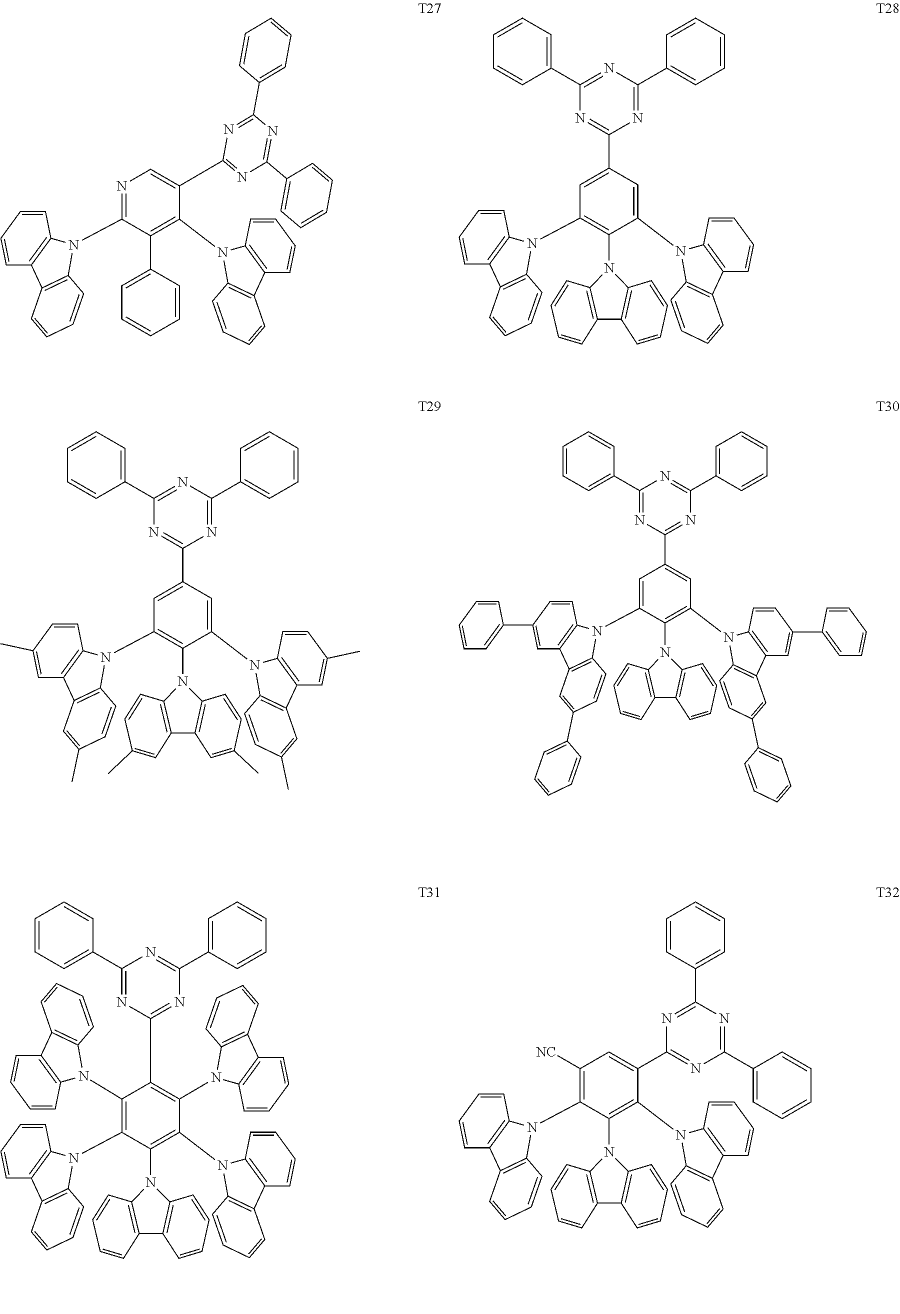

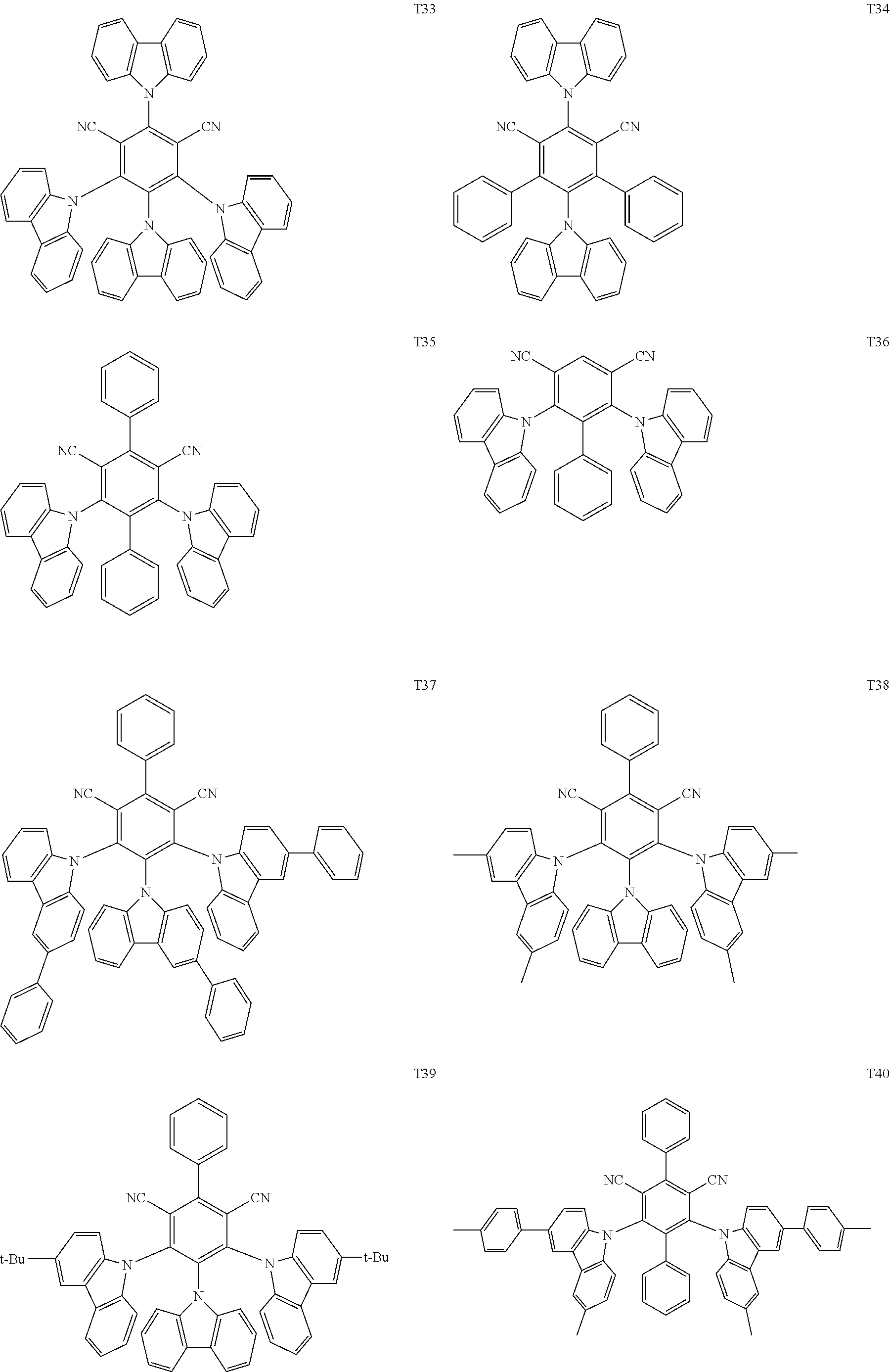

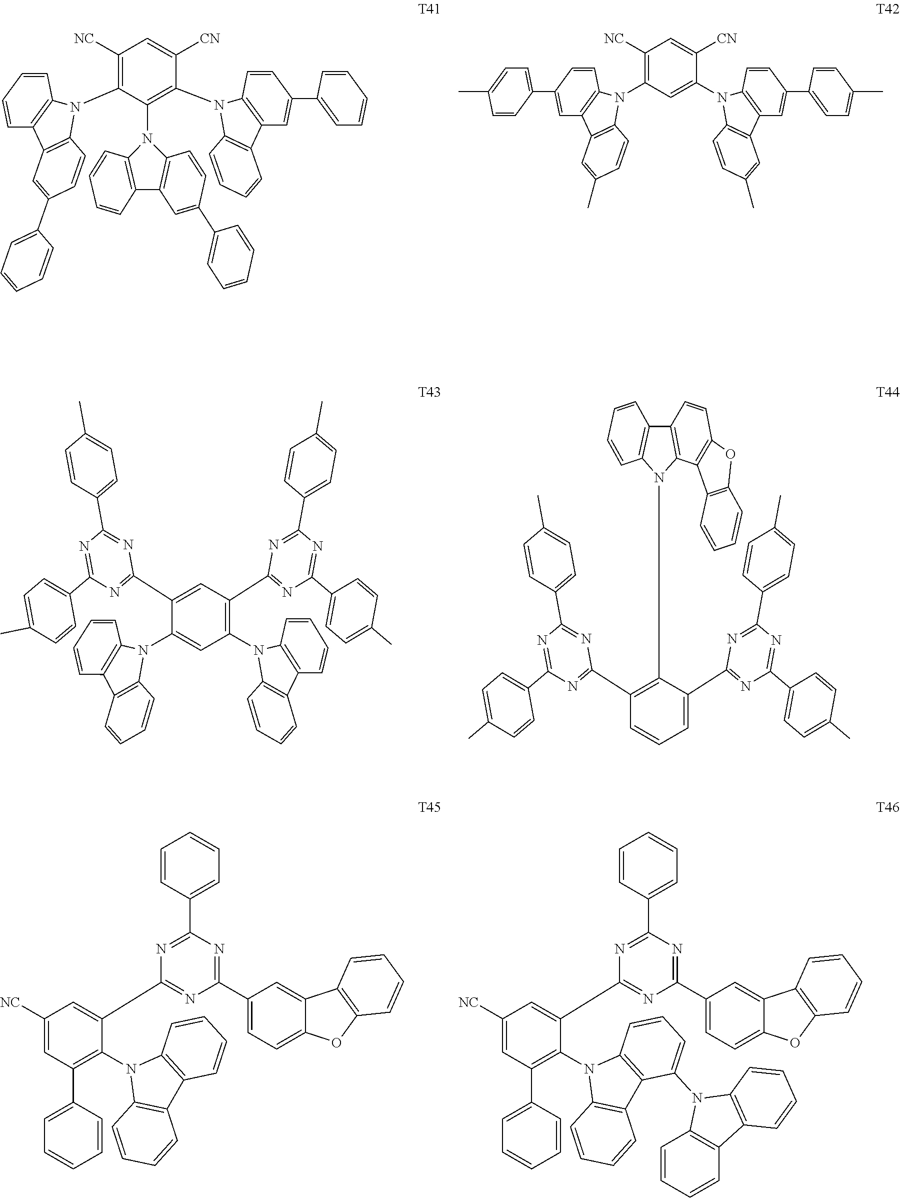

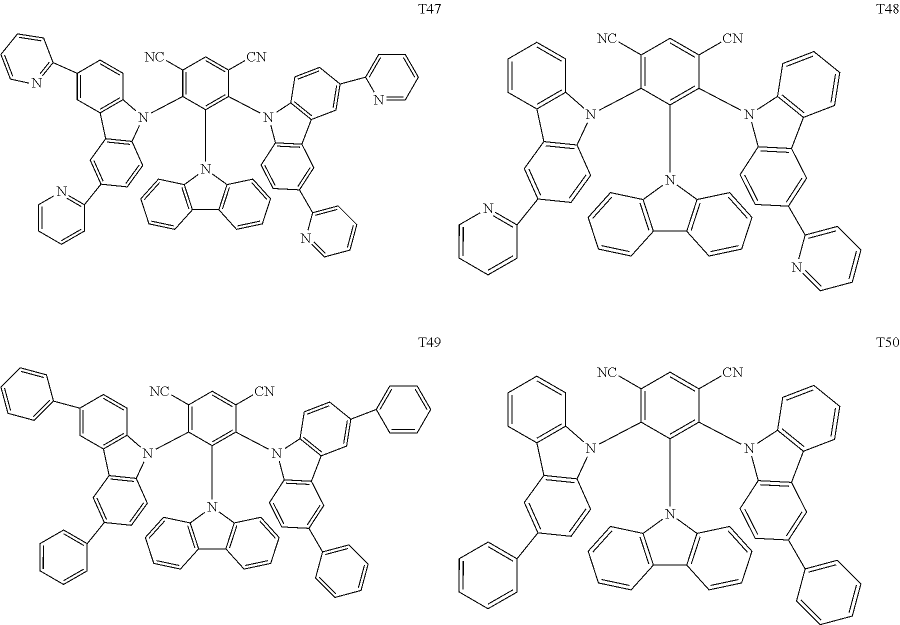 [SMILES: N#Cc1cc(C#N)c(-n2c3ccc(-c4ccccn4)cc3c3cc(-c4ccccn4)ccc32)c(-n2c3ccccc3c3ccccc32)c1-n1c2ccc(-c3ccccn3)cc2c2cc(-c3ccccn3)ccc21 ; N#Cc1cc(C#N)c(-n2c3ccccc3c3cc(-c4ccccn4)ccc32)c(-n2c3ccccc3c3ccccc32)c1-n1c2ccccc2c2cc(-c3ccccn3)ccc21 ; N#Cc1cc(C#N)c(-n2c3ccc(-c4ccccc4)cc3c3cc(-c4ccccc4)ccc32)c(-n2c3ccccc3c3ccccc32)c1-n1c2ccc(-c3ccccc3)cc2c2cc(-c3ccccc3)ccc21 ; N#Cc1cc(C#N)c(-n2c3ccccc3c3cc(-c4ccccc4)ccc32)c(-n2c3ccccc3c3ccccc32)c1-n1c2ccccc2c2cc(-c3ccccc3)ccc21]

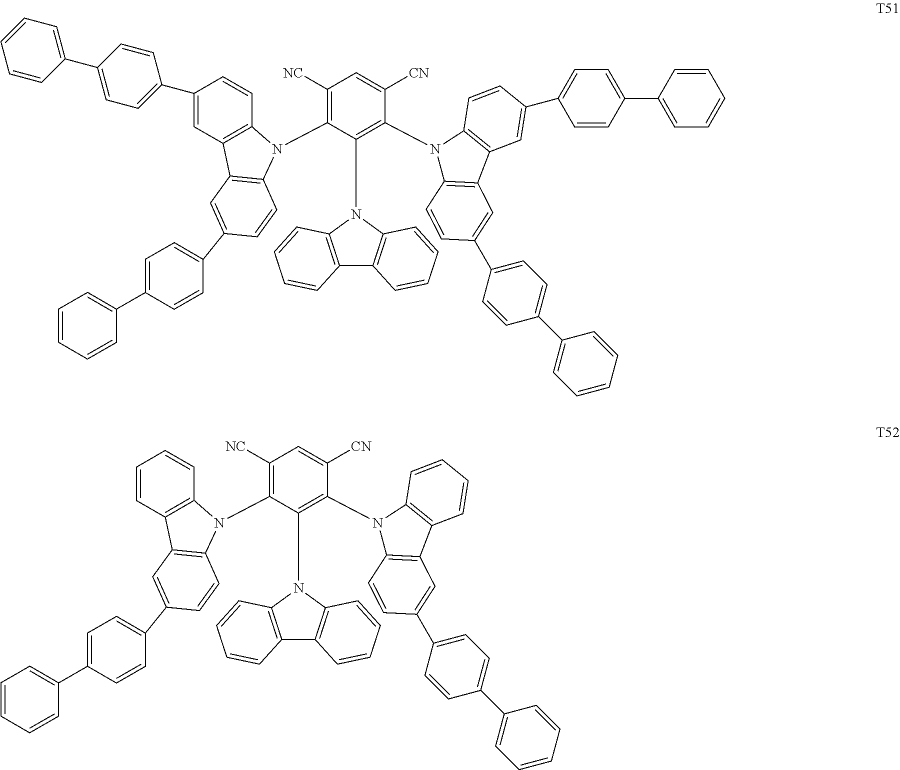 [SMILES: N#Cc1cc(C#N)c(-n2c3ccc(-c4ccc(-c5ccccc5)cc4)cc3c3cc(-c4ccc(-c5ccccc5)cc4)ccc32)c(-n2c3ccccc3c3ccccc32)c1-n1c2ccc(-c3ccc(-c4ccccc4)cc3)cc2c2cc(-c3ccc(-c4ccccc4)cc3)ccc21 ; N#Cc1cc(C#N)c(-n2c3ccccc3c3cc(-c4ccc(-c5ccccc5)cc4)ccc32)c(-n2c3ccccc3c3ccccc32)c1-n1c2ccccc2c2cc(-c3ccc(-c4ccccc4)cc3)ccc21]

Any other known delayed fluorescent materials than the above can be appropriately combined and used as the second organic compound. In addition, unknown delayed fluorescent materials can also be used.

As preferred delayed fluorescent materials, there can be mentioned compounds included in the general formulae described in WO2013/154064, paragraphs 0008 to 0048 and 0095 to 0133; WO2013/011954, paragraphs 0007 to 0047 and 0073-0085; WO2013/011955, 11955, paragraphs 0007 to 0033 and 0059 to 0066; WO2013/081088, paragraphs 0008 to 0071 and 0118 to 0133; JP 2013-25649(1A, paragraphs 0009 to 0046 and 0093 to 0134; JP 2013-116975 A, paragraphs 0008 to 0020 and 0038 to 0040; WO2013/133359, paragraphs 0007 to 0032 and 0079 to 0084; WO2013/161437, paragraphs 0008 to 0054 and 01010121; JP 2014-9352 A, paragraphs 0007 to 0041 and 0060 to 0069; and JP 2014-9224 A, paragraphs 0008 to 0048 and 0067 to 0076; JP 2017 119663 A, paragraphs 0013 to 0025; JP 2017-119664 A, paragraphs 0013 to 0026: JP 2017-222623 A, paragraphs 0012 to 0025; JP 2017-226838 A, paragraphs 0010 to 0050; JP 2018-100411 A, paragraphs 0012 to 0043; WO2018/047853, paragraphs 0016 to 0044; and especially, exemplary compounds therein capable of emitting delayed fluorescence. In addition, also preferably employable here are light emitting materials capable of emitting delayed fluorescence, as described in JP 2013-253121 A, WO2013/133359, WO2014/034535. WO2014/115743, WO2014/122895, WO2014/126200, WO2014/136758, WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP 2015-129240 A, WO2015/129714, WO2015/129715, WO2015/133501, WO2015/136880, WO2015/137244, WO2015/137202, WO2015/137136, WO2015/146541 and WO2015/159541. These patent publications described in this paragraph are hereby incorporated as a part of this description by reference.

A compound represented by the following general formula (1) and capable of emitting delayed fluorescence is preferably employed as the delayed fluorescent material in the present invention. In a preferred embodiment of the present invention, the compound represented by the general formula (1) can be employed as the second organic compound.

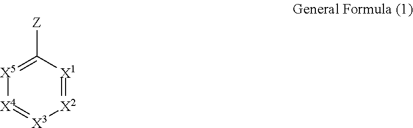

In the general formula (1). X¹ to X⁵ each represent N or C—R. R represents a hydrogen atom or a substituent. When at least two of X¹ to X⁵ are (C—R)'s, these (C—R)'s can be the same as or different from each other. However, at least one of X¹ to X⁵ is C D (where D represents a donor group). When all X¹ to X⁵ are (C—R)'s, Z represents an acceptor group, and at least one of X¹ to X⁵ is N, Z represents a hydrogen atom or a substituent.

Of the compound represented by the general formula (1), especially preferred is a compound represented by the following general formula (2).

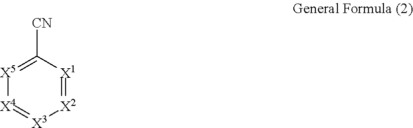

In the general formula (2), X¹ to X⁵ each represent N or C—R. R represents a hydrogen atom or a substituent. When at least two of X¹ to X⁵ are (C—R)'s, these (C—R)'s can be the same as or different from each other. However, at least one of X¹ to X⁵ is C—D (where D represents a donor group).

Regarding the description and the preferred range of the substituent that Z in the general formula (1) represents, reference can be made to the description and the preferred range of the substituent in the general formula (7) to be mentioned hereinunder. The acceptor group that Z in the general formula (1) represents is a group that donates an electron to the ring to which Z bonds, and for example, can be selected from groups having a positive Hammett's σₚ value. The donor group that D in the general formula (1) and the general formula (2) represents is a group that attracts an electron from the ring to which D bonds, and for example, can be selected from groups having a negative Hammett's σₚ value. Hereinafter the acceptor group can be referred to as A.

Here, “Hammett's σₚ value” is one propounded by L. P. Hammett, and is one to quantify the influence of a substituent on the reaction rate or the equilibrium of a para-substituted benzene derivative. Specifically, the value is a constant (σₚ) peculiar to the substituent in the following equation that is established between a substituent and a reaction rate constant or an equilibrium constant in a para-substituted benzene derivative:

log(k/k₀)=ρσₚ

or

log(K/K₀)=ρσₚ

In the above equations, k represents a rate constant of a benzene derivative not having a substituent: k₀ represents a rate constant of a benzene derivative substituted with a substituent; K represents an equilibrium constant of a benzene derivative not having a substituent: K₀ represents an equilibrium constant of a benzene derivative substituted with a substituent; ρ represents a reaction constant to be determined by the kind and the condition of reaction. Regarding the description relating to the “Hammett's σₚ value” and the numerical value of each substituent, reference may be made to the description relating to σₚ value in Hansch. C. et. al., Chem. Rev., 91, 165-195 (1991).

In the general formula (1) and the general formula (2). X¹ to X⁵ each represent N or C—R and at least one of them is C-D. The number of N's of X¹ to X⁵ is 0 to 4, and for example, a case where X¹ and X³ and X⁵, X¹ and X³, X¹ and X⁴, X² and X³, X¹ and X⁵, X² and X⁴, X¹ alone, X² alone, or X³ alone are/is N('s) can be exemplified. The number of (C—D)'s of X¹ to X⁵ is 1 to 5, and is preferably 2 to 5. For example, a case where X¹ and X² and X³ and X⁴ and X⁵,X¹ and X² and X⁴ and X⁵, X¹ and X² and X³ and X⁴,X¹ and X³ and X⁴ and X⁵,X¹ and X³ and X⁵,X¹ and X² and X⁵,X¹ and X² and X⁴,X¹ and X³ and X⁴, X¹ and X³, X¹ and X⁴, X² and X³, X¹ and X⁵, X² and X⁴, X¹ alone, X² alone, or X³ alone are/is (C—D)('s) can be exemplified. At least one of X¹ to X⁵ can be C—A. Here. A represents an acceptor group. The number of (C—A)'s of X¹ to X⁵ is preferably 0 to 2, more preferably 0 or 1. A of C—A is preferably a cyano group, or an unsaturated, nitrogen atom-having heterocyclic aromatic group. X¹ to X⁵ each can be independently C—D or C—A.

When the neighboring two of X¹ to X⁵ are (C—R)'s, the two R's can bond to each other to form a cyclic structure. The cyclic structure to be formed by bonding can be an aromatic ring or an aliphatic ring, or can contain a hetero atom, and further, the cyclic structure can also be a condensed ring of two or more rings. Here the hetero atom is preferably selected from the group consisting of a nitrogen atom, an oxygen atom and a sulfur atom. Examples of the cyclic structure to be formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring, and a quinoline ring. Many rings can be condensed to form a ring such as a phenanthrene ring or a triphenylene ring.

The donor group D in the general formula (1) and the general formula (2) is preferably a group represented by, for example, the following general formula (3).

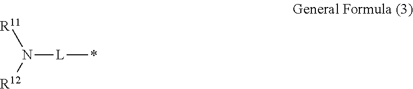

In the general formula (3). R¹¹ and R¹² each independently represent a substituted or unsubstituted alkyl group, a substituted or unsubstituted alkenyl group, a substituted or unsubstituted aryl group, or a substituted or unsubstituted heteroaryl group. R¹¹ and R¹² can bond to each other to form a cyclic structure. L represents a single bond, a substituted or unsubstituted arylene group, or a substituted or unsubstituted heteroarylene group. The substituent that can be introduced into the arylene group or the heteroarylene group of L can be the group represented by the general formula (1) or the general formula (2), or cab be a group represented by the general formulae (3) to (6) to be mentioned hereinunder. The groups represented by these (1) to (6) can be introduced in an amount up to the maximum number of the groups capable of being introduced into L. In the case where plural groups of the general formulae (1) to (6) are introduced, these substituents can be the same as or different from each other. * indicates the bonding position to the carbon atom (C) that constitutes the ring skeleton of the ring in the general formula (1) or the general formula (2).

Here, “alkyl group” can be linear, branched or cyclic. Two or more of a linear moiety, a cyclic moiety and a branched moiety can be in the group as mixed. The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group of a substituent can be further substituted with an aryl group.

“Alkenyl group” can be linear, branched or cyclic. Two or more of a linear moiety, a cyclic moiety and a branched moiety can be in the group as mixed. The carbon number of the alkyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted with an aryl group.

“Aryl group” and “Heteroaryl group” each can be a single ring or can be a condensed ring of two or more kinds of rings. In the case of a condensed ring, the number of the rings that are condensed is preferably 2 to 6, and, for example, can be selected from 2 to 4. Specific examples of the ring include a benzene ring, a pyridine ring, a pyrimidine ring, a triazine ring, a naphthalene ring, an anthracene ring, a phenanthrene ring, a triphenylene ring, a quinoline ring, a pyrazine ring, a quinoxaline ring, and a naphthyridine ring. Specific examples of the aryl ring or the heteroaryl ring include a phenyl group, a 1-naphthyl group, a 2-naphthyl group, a 1-anthracenyl group, a 2-anthracenyl group, a 9-anthracenyl group, a 2-pyridyl group, a 3-pyridyl group, and a 4-pyridyl group. For “arylene group” and “heteroarylene group”, the valance of the aryl group and the heteroaryl group is exchanged from 1 to 2, and the thus-exchanged description can be referred to.

The substituent means a monovalent group that can substitute for a hydrogen atom, and does not mean a concept of condensation. Regarding the description and the preferred range of the substituent, reference can be made to the description and the preferred range of the substituent in the general formula (7) to be mentioned hereinunder.

The group represented by the general formula (3) is preferably a group represented by any of the following general formulae (4) to (6).

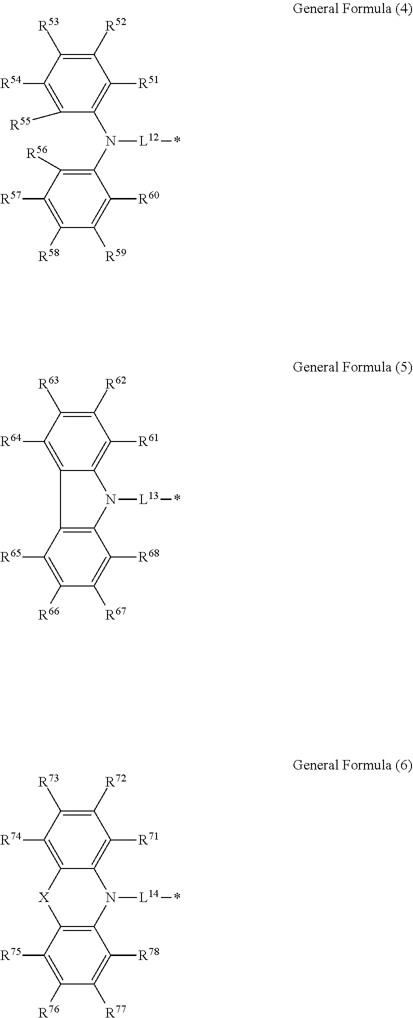

In the general formulae (4) to (6), R⁵¹ to R⁶⁰, R⁶¹ to R⁶⁸, and R⁷¹ to R⁷⁸ each independently represent a hydrogen atom or a substituent. Regarding the description and the preferred range of the substituent as referred to herein, reference can be made to the description and the preferred range of the substituent in the general formula (7) to be mentioned hereinunder. R⁵¹ to R⁶⁰, R⁵¹ to R⁶⁸, and R⁷¹ to R⁷⁸ each are also preferably a group represented by any of the above-mentioned general formulae (4) to (6). The number of the substituents in the general formulae (4) to (6) is not specifically limited. Cases where all are unsubstituted (that is, all are hydrogen atoms) are also preferred. In the case where each of the general formulae (4) to (6) has two or more substituents, these substituents can be the same or different. When the general formulae (4) to (6) have substituents, the substituents are preferably any of R⁵² to R⁵⁹ in the case of the general formula (4), or any of R⁶² to R⁶⁷ in the case of the general formula (5), or any of R⁷² to R⁷⁷ in the case of the general formula (6).

In the general formulae (4) to (6), R⁵¹ and R⁵², R⁵² and R⁵³, R⁵³ and R⁵⁴, R⁵⁴ and R⁵⁵, R⁵⁵ and R⁵⁶, R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³, R⁶³ and R⁶⁴, R⁶⁵ and R⁶⁶, R⁶⁶ and R⁶⁷, R⁶⁷ and R⁶⁸, R⁷¹ and R⁷², R⁷² and R⁷³, R⁷³ and R⁷⁴, R⁷⁵ and R⁷⁶, R⁷⁶ and R⁷⁷, and R⁷⁷ and R⁷⁸ each can bond to each other to form a cyclic structure. Regarding the description and the preferred examples of the cyclic structure, reference can be made to the description and the preferred examples of the cyclic structure for X¹ to X⁵ in the above-mentioned general formula (1) and general formula (2).

In the general formula (6), X represents an oxygen atom, a sulfur atom, a substituted or unsubstituted nitrogen atom, a substituted or unsubstituted carbon atom a substituted or unsubstituted silicon atom or a carbonyl group that is divalent and has a linking chain length of one atom, or represents a substituted or unsubstituted ethylene group, a substituted or unsubstituted vinylene group, a substituted or unsubstituted o-arylene group or a substituted or unsubstituted heteroarylene group that is divalent and has a linking chain length of two atoms. Regarding the specific examples and the preferred range of the substituents, reference can be made to the description of the substituents in the general formula (1) and the general formula (2).

In the general formulae (4) to (6), L¹² to L¹⁴ each represent a single bond, a substituted or unsubstituted arylene group or a substituted or unsubstituted heteroarylene group. Regarding the description and the preferred range of the arylene group and the heteroarylene group that L¹² to L¹⁴ represent, reference can be made to the description and the preferred range of the arylene group and the heteroarylene group that L represents. L¹² to L¹⁴ each are preferably a single bond, or a substituted or unsubstituted arylene group. Here the substituent for the arylene group and the heteroarylene group can be the group represented by the general formulae (1) to (6). The group represented by the general formulae (1) to (6) can be introduced into L¹² to L¹⁴ in an amount up to the maximum number of the substituents that can be introduced thereinto. In the case where plural groups of the general formulae (1) to (6) are introduced, these substituents can be the same as or different from each other. * indicates the bonding position to the carbon atom (C) that constitutes the ring skeleton of the ring in the general formula (1) or the general formula (2).

A compound represented by the following general formula (7) and capable of emitting delayed fluorescence can be especially preferably used as the delayed fluorescent material in the present invention. In a preferred embodiment of the present invention, the compound represented by the general formula (7) can be employed as the second organic compound.

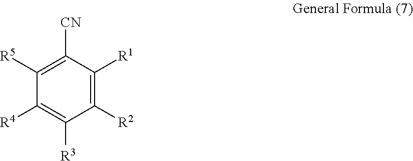

In the general formula (7), 0 to 4 of R¹ to R⁵ each represent a cyano group, at least one of R¹ to R⁵ represents a substituted amino group, and the remaining R¹ to R⁵ are hydrogen atoms, or represent any other substituent than a cyano group and a substituted amino group.

Here the substituted amino group is preferably a substituted or unsubstituted diarylamino group, and the two aryl groups constituting the substituted or unsubstituted diarylamino group can bond to each other. The bonding can be made via a single bond (in such a case, a carbazole ring is formed), or via a linking group such as —O—, —S—, —N(R⁶)—, —C(R⁷)(R⁸)—, or —Si(R⁹)(R¹⁰)—. Here, R⁶ to R¹⁰ each represent a hydrogen atom or a substituent, and R⁷ and R⁸, and R⁹ and R¹⁰ each can bond to each other to form a cyclic structure.

A substituted amino group can be any of R¹ to R⁵, and for example, R¹ and R², R¹ and R³, R¹ and R⁴, R¹ and R⁵, R² and R³, R² and R⁴, R¹ and R² and R³, R¹ and R² and R⁴, R¹ and R² and R⁵, R¹ and R³ and R⁴,R¹ and R³ and R⁵,R² and R³ and R⁴,R¹ and R² and R³ and R⁴, R¹ and R² and R³ and R⁵, R¹ and R² and R⁴ and R⁵, and R¹ and R² and R³ and R⁴ and R⁵ each can be a substituted amino group. A cyano group can also be any of R¹ to R⁵, and for example, R¹, R², R³, R¹ and R², R¹ and R³, R¹ and R⁴, R¹ and R⁵, R² and R³,R² and R⁴,R¹ and R² and R³,R¹ and R² and R⁴, R¹ and R² and R⁵,R¹ and R³ and R⁴, R¹ and R³ and R⁵, and R² and R³ and R⁴ each can be a cyano group.

R¹ to R⁵ that are neither a cyano group nor a substituted amino group each represent a hydrogen atom or a substituent. Examples of the substituent referred to herein include a substituent group A that contains a hydroxy group, a halogen atom (e.g., fluorine atom, chlorine atom, bromine atom, iodine atom), an alkyl group (for example, having 1 to 40 carbon atoms), an alkoxy group (for example, having 1 to 40 carbon atoms), an alkylthio group (for example, having 1 to 40 carbon atoms), an aryl group (for example, having 6 to 30 carbon atoms), an aryloxy group (for example, having 6 to 30 carbon atoms), an arylthio group (for example, having 6 to 30 carbon atoms), a heteroaryl group (for example, having 5 to 30 ring skeleton constituting atoms), a heteroaryloxy group (for example, having 5 to 30 ring skeleton constituting atoms), a heteroarylthio group (for example, having 5 to 30 ring skeleton constituting atoms), an acyl group (for example, having 1 to 40 carbon atoms), an alkenyl group (for example, having 1 to 40 carbon atoms), an alkynyl group (for example, having 1 tot 40 carbon atoms), an alkoxycarbonyl group (for example, having 1 to 40 carbon atoms), an aryloxycarbonyl group (for example, having 1 to 40 carbon atoms), a heteroaryloxycarbonyl group (for example, having 1 to 40 carbon atoms), a silyl group (for example, trialkylsilyl group having 1 to 40 carbon atoms), a nitro group, and groups listed herein and substituted with one or more groups also listed herein. Preferred examples of the substituent of the diarylamino group in which the aryl group is substituted also include the substituents of the substituent group A, and further include a cyano group and a substituted amino group.

Regarding the compound group included in the general formula (7) and specific examples of the compounds, reference can be made to WO2013/154064, paragraphs 0008 to 0048; WO2015/080183, paragraphs 0009 to 0030; WO2015/129715, paragraphs 0006 to 0019; JP2017-119663A, paragraphs 0013 to 0025; JP2017-119664A, paragraphs 0013 to 0026; which are hereby incorporated by reference as a part of the present specification.

Further a compound represented by the following general formula (8) and capable of emitting delayed fluorescence can also be especially preferably used as the delayed fluorescent material in the present invention. In a preferred embodiment of the present invention, the compound represented by the general formula (8) can be employed as the second organic compound.

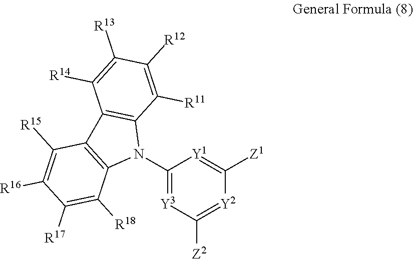

In the general formula (8), any two of Y¹, Y² and Y³ are nitrogen atoms and the remaining one is a methine group, or all of Y¹, Y² and Y³ are nitrogen atoms. Z¹ and Z² each independently represent a hydrogen atom or a substituent. R¹¹ to R¹⁸ each independently represent a hydrogen atom or a substituent, and at least one of R¹¹ to R¹⁸ is preferably a substituted or unsubstituted arylamino group or a substituted or unsubstituted carbazolyl group. The benzene ring to constitute the arylamino group and the benzene ring to constitute the carbazolyl group each can form a single bond or a linking group together with any of R¹¹ to R¹⁸. The compound represented by the general formula (8) contains at least two carbazole structures in the molecule. Examples of the substituent that Z¹ and Z² can take include the substituents in the above-mentioned substituent group A. Specific examples of the substituent that R¹¹ to R¹⁸, the arylamino group and the carbazolyl group can take include the substituents in the substituent group A, and a cyano group, a substituted arylamino group and a substituted alkylamino group. R¹¹ and R¹², R¹² and R¹³,R¹⁴ and R¹⁴, R¹⁵ and R¹⁶,R¹⁶ and R¹⁷, and R¹⁷ and R¹⁸ each can bond to each other to form a cyclic structure.

Among the compounds represented by the general formula (8), those represented by the following general formula (9) are especially useful

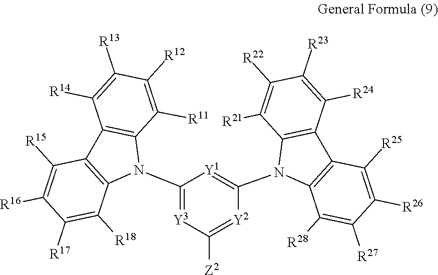

In the general formula (9), any two of Y¹, Y² and Y³ are nitrogen atoms and the remaining one is a methine group, or all of Y¹, Y² and Y³ are nitrogen atoms. Z² represents a hydrogen atom or a substituent. R¹¹ to R¹⁸ and R²¹ to R²⁸ each independently represent a hydrogen atom or a substituent. At least one of R¹¹ to R¹⁸ and/or at least one of R²¹ to R²⁸ are/is preferably a substituted or unsubstituted arylamino group or a substituted or unsubstituted carbazolyl group. The benzene ring to constitute the arylamino group and the benzene ring to constitute the carbazolyl group each can form a single bond or a linking group together with any of R¹¹ to R¹⁸ or R²¹ to R²⁸. Examples of the substituent that Z² can take include the substituents in the above-mentioned substituent group A. Specific examples of the substituent that R¹¹ to R¹⁸, R²¹ to R²⁸, the arylamino group and the carbazolyl group can take include the substituents in the substituent group A. and a cyano group, a substituted arylamino group and a substituted alkylamino group. R¹¹ and R¹², R¹² and R¹³, R¹³ and R¹⁴, R¹⁵ and R¹⁶, R¹⁶ and R¹⁷, R¹⁷ and R¹⁸, R²¹ and R²², R²² and R²³, R²³ and R²⁴, R²⁵ and R²⁶, R²⁶ and R²⁷, and R²⁷ and R²⁸ each can bond to each other to form a cyclic structure.

Regarding the compound group included in the general formula (9) and specific examples of the compounds, reference can be made to the compounds described in WO2013/081088, paragraphs 0020 0062 that is hereby incorporated by reference as a part of the present invention, and in Appl. Phys. Let, 98, 083302 (2011).

Also a compound represented by the following general formula (10) and capable of emitting delayed fluorescence can be especially preferably used as the delayed fluorescent material in the present invention.

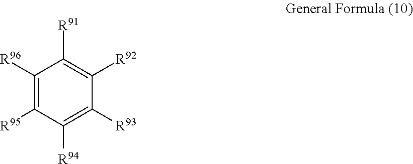

In the general formula (10), R⁹¹ to R⁹⁶ each independently represent a hydrogen atom, a donor group, or an acceptor group, and at least one of them is a donor group and at least two are acceptor groups. The substitution positions of at least two acceptor groups are not specifically limited, but preferably include two acceptor groups that are in a meta-position relationship. For example, when R⁹¹ is a donor group, preferred examples include a structure where at least R⁹² and R⁹⁴ are acceptor groups, or a structure where at least R⁹² and R⁹⁶ are acceptor groups. The acceptor groups existing in the molecule can be all the same as or different from each other, but a structure where all have the same structure can be selected. The number of the acceptor groups is preferably 2 to 3, and for example, 2 can be selected. Two or more donor groups can exist, and in that case, all the donor groups can be the same as or different from each other. The number of the donor groups is preferably 1 to 3, and for example, it can be one only or can be two. Regarding the description and a preferred range of the donor group and the acceptor group, reference can be made to the description and the preferred range of D and Z in the general formula (1). In particular, the donor group in the general formula (10) is preferably represented by the general formula (3), and the acceptor group is preferably a cyano group or is represented by the following general formula (11).

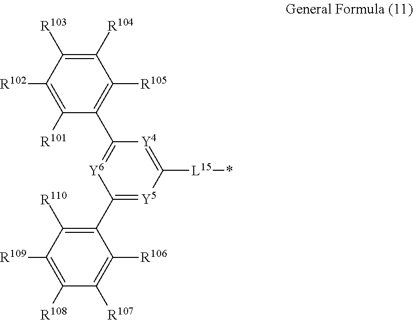

In the general formula (11), Y⁴ to Y⁶ each represent a nitrogen atom or a methine group, and at least one is a nitrogen atom, and preferably all are nitrogen atoms. R¹⁰¹ to R¹¹⁰ each independently represent a hydrogen atom or a substituent, and at least one is preferably an alkyl group. Regarding the description and a preferred range of the substituent as referred to herein, reference can be made to the description and the preferred range of the substituent in the general formula (7) mentioned hereinabove. L¹⁵ represents a single bond or a linking group, for which reference can be made to the description and the preferred range of L in the general formula (3) mentioned hereinabove. In one preferred embodiment of the present invention. L¹⁵ in the general formula (11) is a single bond. * indicates a bonding position to the carbon atom (C) that constitutes the ring skeleton of the ring in the general formula (10).

In another preferred embodiment of the present invention, a compound represented by the following general formula (12) can be employed as the second organic compound.

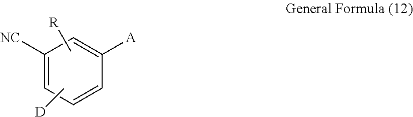

Among the compounds represented by the general formula (12), preferred are the compound represented by the following general formula (13) and the compound represented by the following general formula (14).

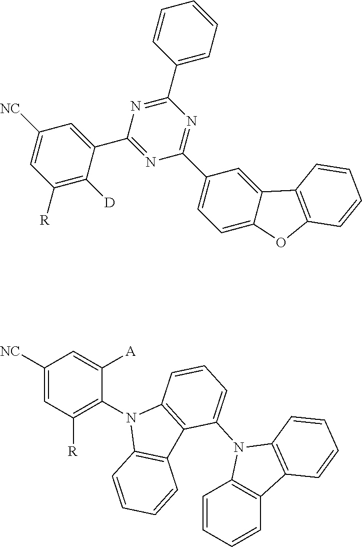

In the general formulae (12) to (14), D represents a donor group, A represents an acceptor group. R represents a hydrogen atom or a substituent. Regarding the description and a preferred range of the donor group and the acceptor group, reference can be made to the corresponding description and the preferred range of the general formula (l) mentioned above. Examples of the substituent of R include an alkyl group, and an aryl group optionally substituted with one group or a combination of two or more selected from the group consisting of an alkyl group and an aryl group.

Specific preferred examples of the donor group of D in the general formulae (12) to (14) are shown below. In the following specific examples, * indicates a bonding position, and “D” represents deuterium.

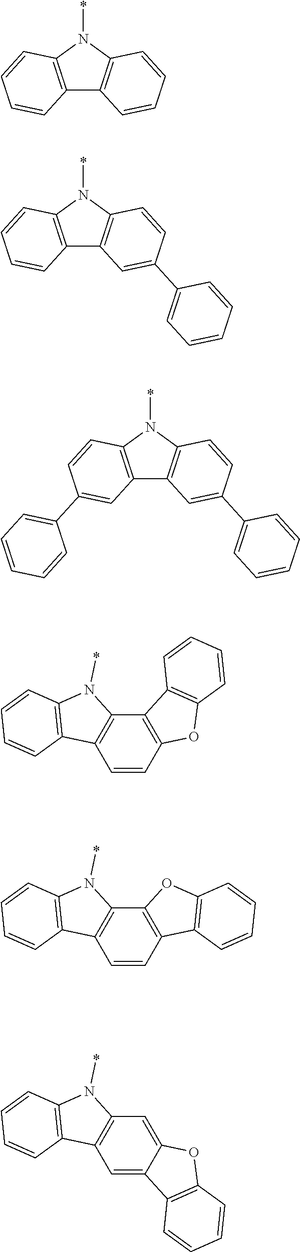

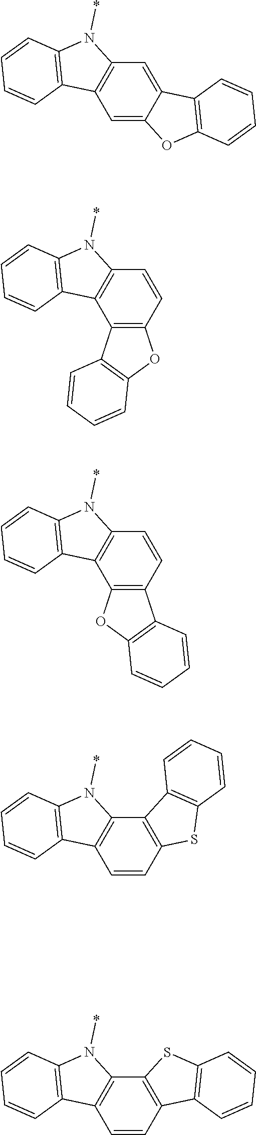

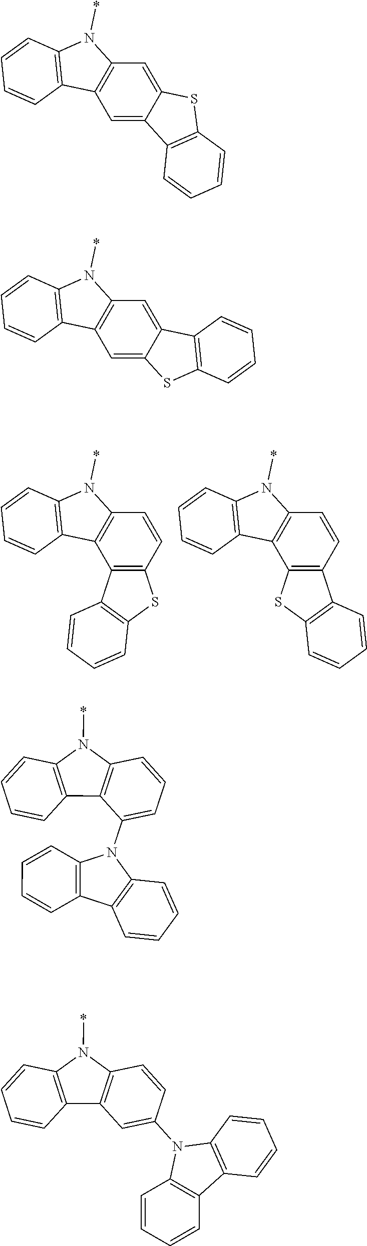

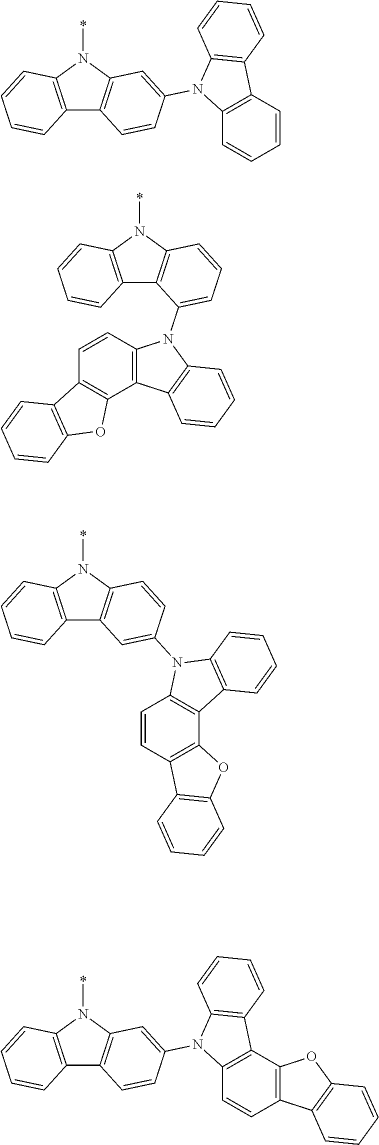

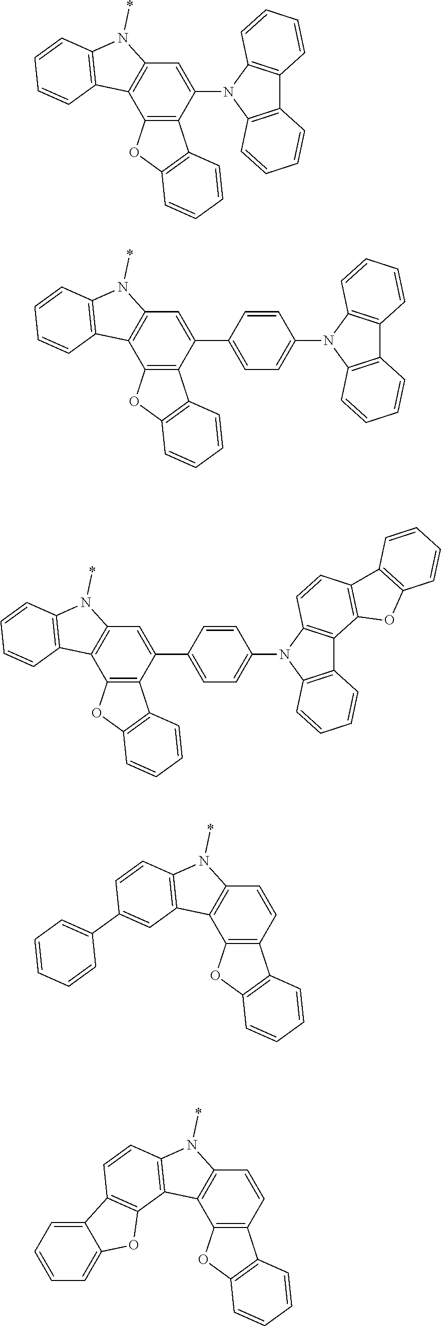

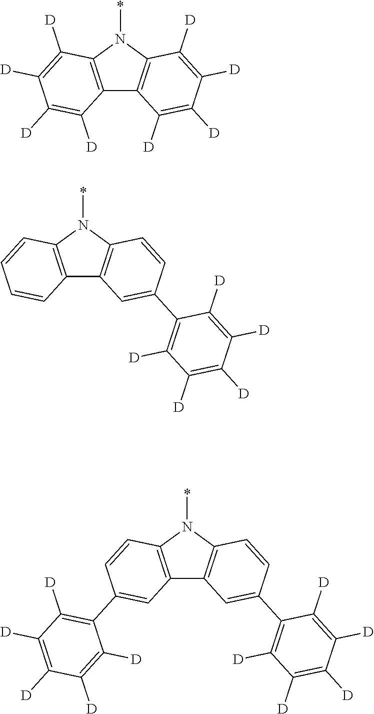

Specific preferred examples of the acceptor group of A in the general formulae (12) to (14) are shown below. In the following specific examples, * indicates a bonding position, and “D” represents deuterium.

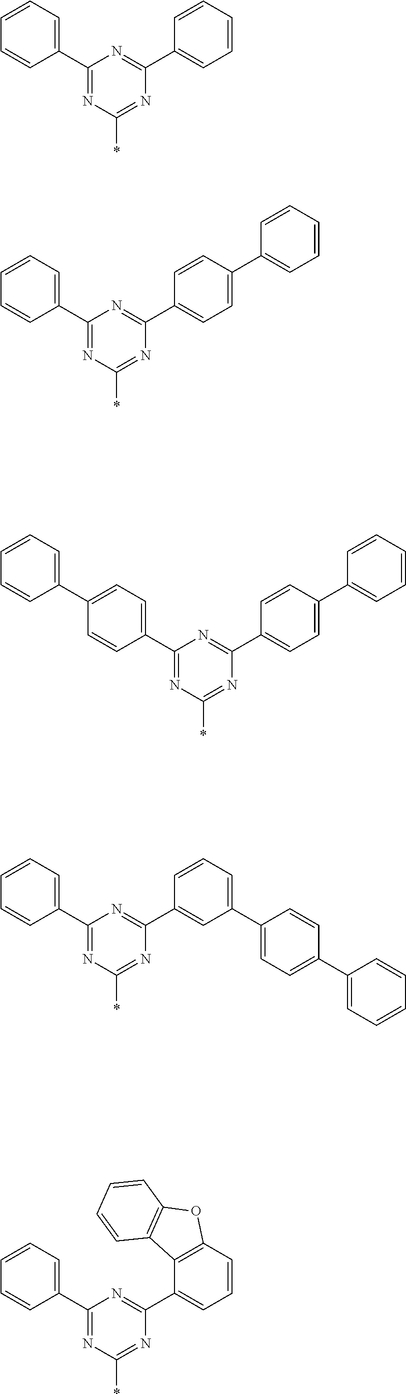

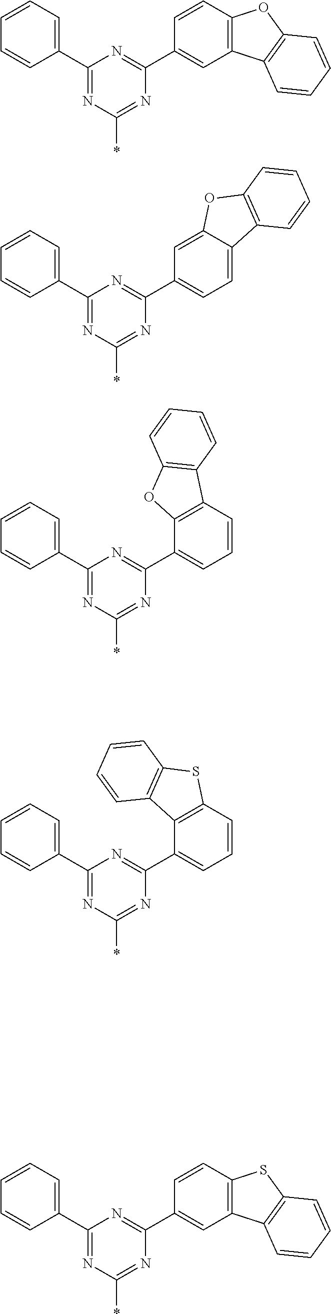

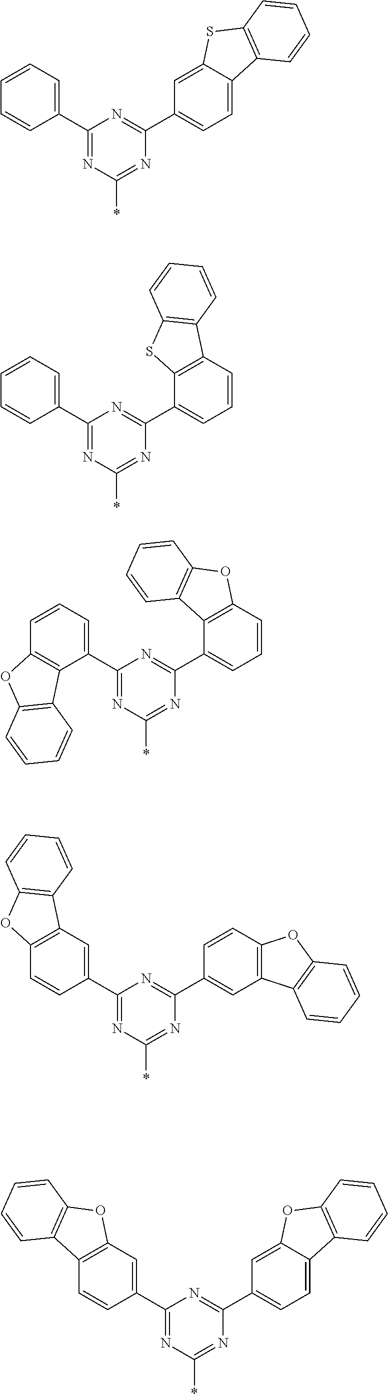

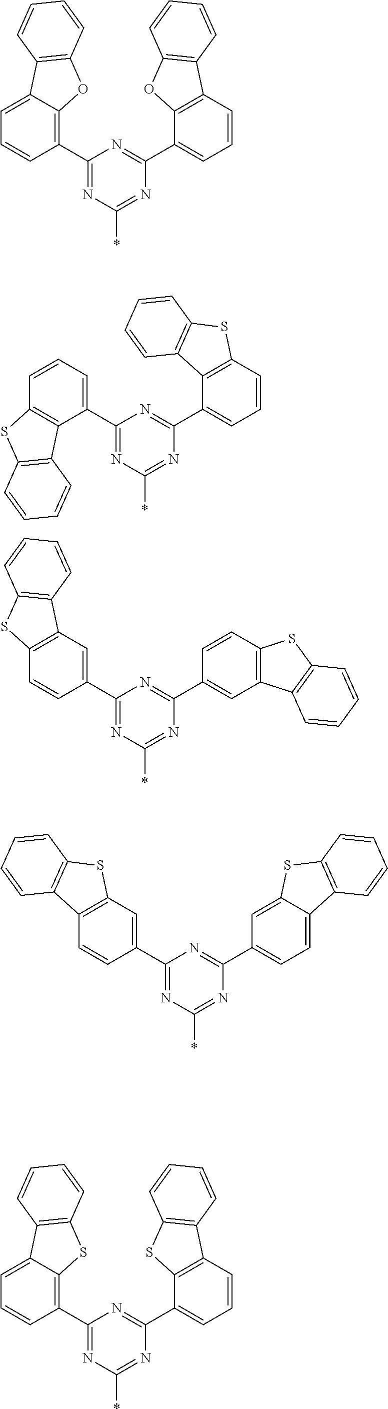

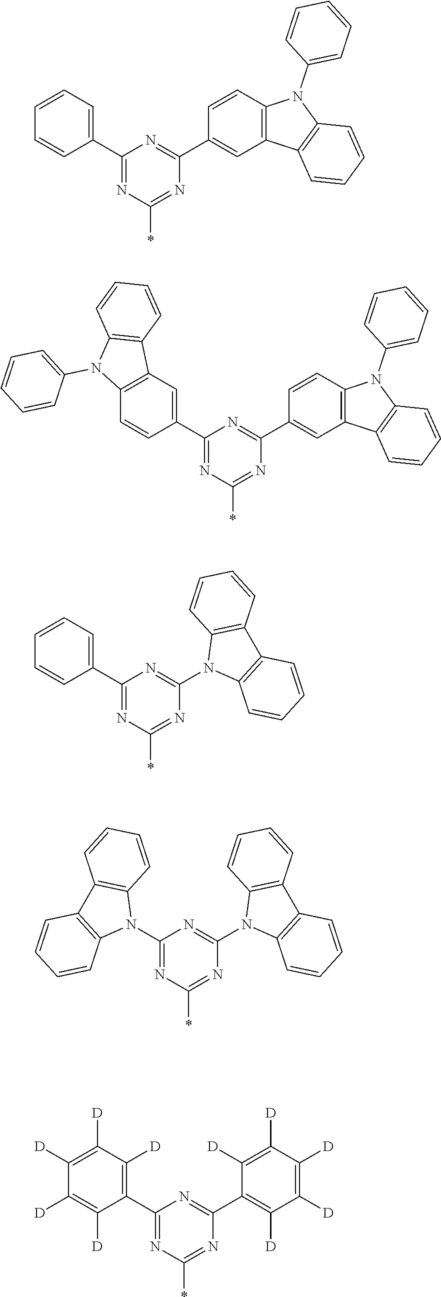

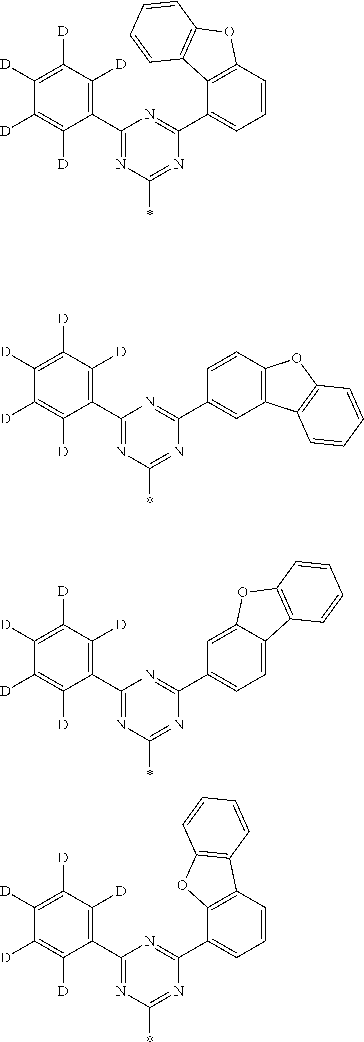

Preferred examples of R in the general formulae (12) to (14) are shown below. In the following specific examples, * indicates a bonding position, and “D” represents deuterium.

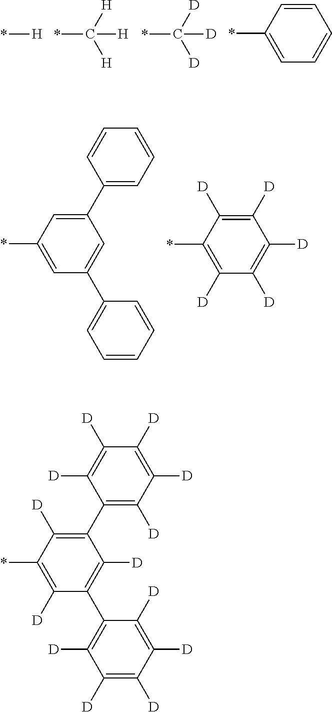

### (Third Organic Compound)

The third organic compound is a compound having a smaller lowest excited singlet energy than the first organic compound, the second organic compound and the fourth organic compound. The third organic compound is a compound having a smaller lowest excited triplet energy than the first organic compound and the second organic compound and having a larger lowest excited triplet energy than the fourth organic compound. The organic light emitting device of the present invention emits fluorescence derive from the third organic compound. Light emission from the third organic compound generally includes delayed fluorescence. The maximum component of light emission from the organic light emitting device of the present invention is light emission from the third organic compound. Specifically, of the light emission from the organic light emitting device of the present invention, the amount of light emission from the third organic compound is the largest. The third organic compound receives energy from the first organic compound in an excited singlet state, from the second organic compound in an excited singlet state, from the fourth organic compound in an excited singlet state and from the second organic compound that has been in an excited singlet state through reverse intersystem crossing from an excited triplet state, and thus transitions into an excited singlet state. In a preferred embodiment of the present invention, the third organic compound receives energy from the second organic compound in an excited singlet state and from the second organic compound that has been in an excited singlet state through reverse intersystem crossing from an excited triplet state, and thus transitions into an excited singlet state. The resultant third organic compound thus in an excited singlet state emits fluorescence when thereafter returning back to a ground state.

The fluorescent material to be used as the third organic compound is not specifically limited so far as it can receive energy from the first organic compound, the second organic compound and the fourth organic compound in the manner as above to emit light, and the light emission can include any of fluorescence, delayed fluorescence and phosphorescence. Preferably, the light emission includes fluorescence and delayed fluorescence, and more preferred is a case where the maximum component of light emission from the third organic compound is fluorescence.

Two or more kinds of third organic compounds can be used as combined so far as they satisfy the requirements in the present invention. For example, by using two or more kinds of the third organic compounds that differ in the emission color, light of a desired color can be emitted. Also by using one kind of the third organic compound, monochromatic emission can be made by the third organic compound.

In the present invention, the maximum emission wavelength of the compound usable as the third organic compound is not specifically limited. Therefore, a light emitting material having a maximum emission wavelength in a visible range (380 to 780 nm) or having a maximum emission wavelength in an IR range (780 nm to 1 mm) can be appropriately selected and used here. Preferred is a fluorescent material having a maximum emission wavelength in a visible range. For example, a light emitting material of which the maximum emission wavelength in a range of 380 to 780 nm falls within a range of 380 to 570 nm can be selected and used, or a light emitting material of which the maximum emission wavelength falls within a range of 380 to 500 nm can be selected and used, or a light emitting material of which the maximum emission wavelength falls within a range of 380 to 480 nm can be selected and used, or a light emitting material of which the maximum emission wavelength falls within a range of 420 to 480 nm can be selected and used.

In a preferred embodiment of the present invention, the second organic compound and the third organic compound are so selected and combined that the emission wavelength range of the former and the adsorption wavelength range of the latter can overlap with each other. Especially preferably, the edge in the short wavelength side of the emission spectrum of the second organic compound overlaps with the edge on the long wavelength side of the absorption spectrum of the third organic compound.

Hereinunder shown are preferred compounds usable as the third organic compound. In the structural formulae of the compounds exemplified below, Et represents an ethyl group.

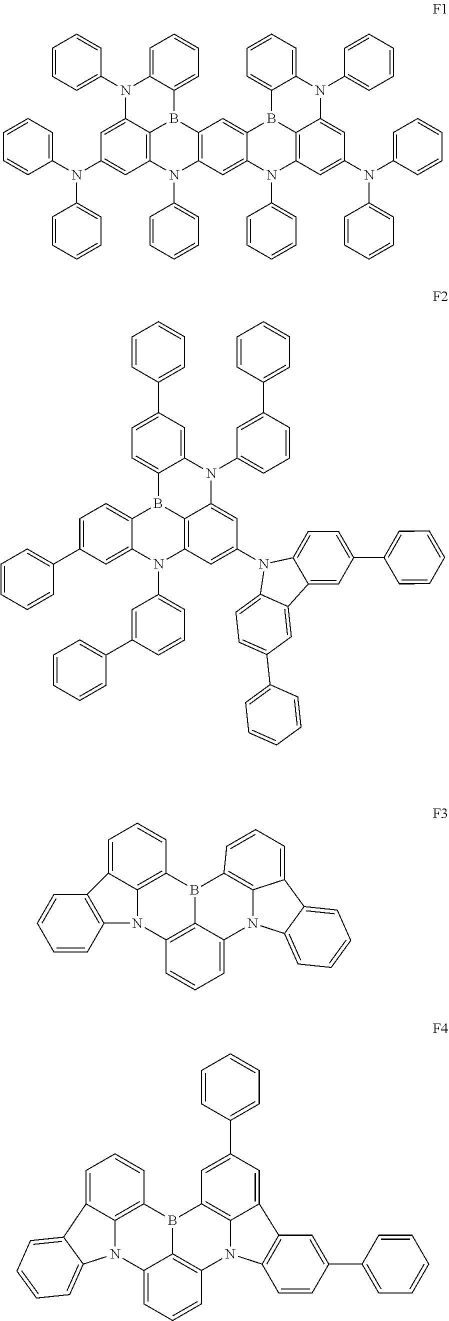 [SMILES: c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1ccc(-c2cccc(N3c4cc(-c5ccccc5)ccc4B4c5ccc(-c6ccccc6)cc5N(c5cccc(-c6ccccc6)c5)c5cc(-n6c7ccc(-c8ccccc8)cc7c7cc(-c8ccccc8)ccc76)cc3c54)c2)cc1 ; c1cc2c3c(c1)-n1c4ccccc4c4cccc(c41)B3c1cccc3c4ccccc4n-2c13 ; c1ccc(-c2ccc3c(c2)c2cc(-c4ccccc4)cc4c2n3-c2cccc3c2B4c2cccc4c5ccccc5n-3c24)cc1]

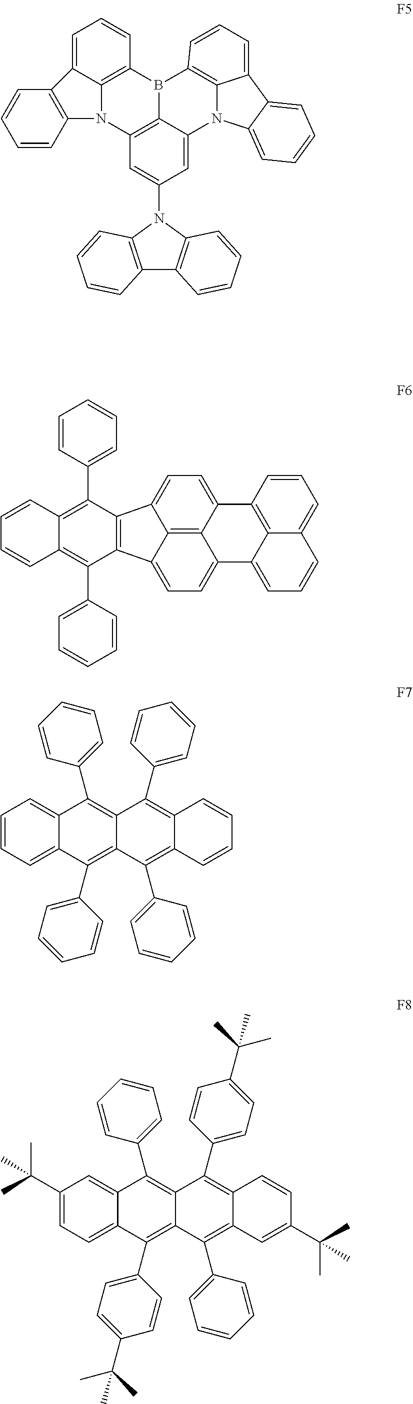

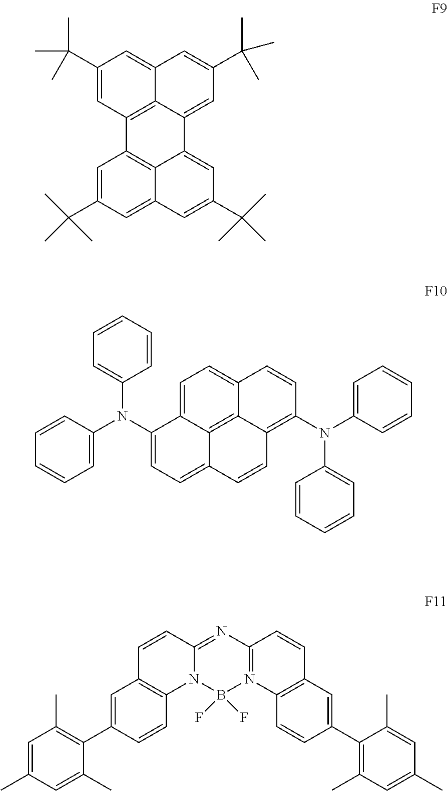

A preferred compound group includes Compounds F1 to F5 and derivatives having a skeleton thereof. The derivatives include compounds substituted with an alkyl group, an aryl group, a heteroaryl group or a diarylamino group.

Also compounds described in WO2015/022974, paragraphs 0220 to 0239 are especially preferably usable as the third organic compound in the present invention.

### (Fourth Organic Compound)

The fourth organic compound is a compound having a smaller lowest excited singlet energy than the first organic compound and having a larger lowest excited singlet energy than the second organic compound and the third organic compound. Also the fourth organic compound is a compound having a smaller lowest excited triplet energy than the first organic compound, the second organic compound and the third organic compound. In the organic light emitting device of the present invention, the fourth organic compound receives energy from the first organic compound, the second organic compound and the third organic compound in an excited triplet state to transition into an excited triplet state. In particular, the fourth organic compound can receive energy from the second organic compound and the third organic compound in an excited triplet state to deactivate the triplet excitons in these second and third organic compounds, and therefore the fourth organic compound can suppress the influence of triplet-triplet interaction and triplet-charge interaction in these organic compounds to improve device durability.

The fourth organic compound can be any one satisfying the requirement (a) and the requirement (b). In one preferred embodiment of the present invention, the fourth organic compound is a compound represented by the following general formula (15).

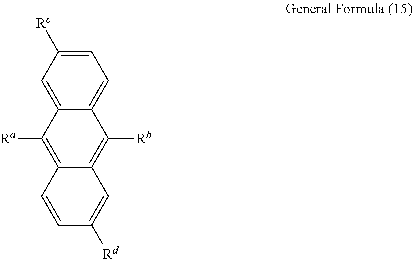

In the general formula (15), R^{a} and R^{b} each independently represent a substituted or unsubstituted aryl group. R^{c} and R^{d} each independently represent a hydrogen atom, a substituted or unsubstituted alkyl group, a substituted or unsubstituted alkoxy group, a substituted or unsubstituted aryl group, a substituted or unsubstituted aryloxy group, a substituted or unsubstituted amino group, a halogen atom, a cyano group, or a substituted or unsubstituted silyl group. R^{c} and R^{d} each are preferably a hydrogen atom or a substituted or unsubstituted aryl group.

The substituent that the alkyl group, the alkoxy group, the aryl group, the aryloxy group and the silyl group can have in the general formula (15) includes an alkyl group, an alkoxy group, an aryl group, an aryloxy group, a halogen atom a cyano group and a silyl group. Preferably, the substituent includes an alkyl group and an aryl group.

For the aryl group, the alkyl group, the aryl moiety in the aryloxy group and the alkyl moiety in the alkoxy group, reference can be made to the description and the specific examples of the aryl group and the alkyl group in the general formula (3). Examples of the halogen atom include a fluorine atom, a chlorine atom, a bromine atom and an iodine atom. The silyl group is preferably a substituted or unsubstituted trialkylsilyl group, and for the alkyl moiety that constitutes the trialkylsilyl group, reference can be made to the description and the specific examples of the alkyl group in the general formula (3). The aryl group can be condensed with a hetero atom-containing ring. Examples of the hetero atom include a nitrogen atom, an oxygen atom and a sulfur atom.

In one preferred embodiment of the present invention, R^{a} and R^{b} are the same, and R^{c} and R^{d} are hydrogen atoms. In another preferred embodiment of the present invention, R^{a} and R^{b} differ, and R^{c} and R^{d} are hydrogen atoms.

In one preferred embodiment of the present invention, at least one of R^{c} and R^{d} is a hydrogen atom.

In one preferred embodiment of the present invention, R^{a}, R^{b} and R^{c} each are independently a substituted or unsubstituted aryl group. In that case. R^{d} can be a hydrogen atom. Or R^{d} can also be a substituted or unsubstituted aryl group.

In one preferred embodiment of the present invention, the fourth organic compound is a compound represented by the following general formula (16).

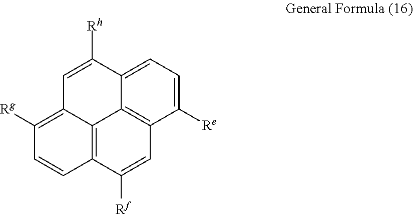

In the general formula (16), R^{e}, R^{f}, R^{g} and R^{h} each independently represent a hydrogen atom, a substituted or unsubstituted alkyl group, a substituted or unsubstituted aryl group, a substituted or unsubstituted alkoxy group, a substituted or unsubstituted aryloxy group, a substituted or unsubstituted amino group, a halogen atom, a cyano group, or a substituted or unsubstituted silyl group. Regarding the description and the preferred range of these substituents, reference can be made to the description and the preferred range of the corresponding substituents in the general formula (15). In one preferred embodiment of the present invention. R^{c} and R^{g} each are independently a substituted or unsubstituted aryl group, a substituted or unsubstituted alkoxy group, a substituted or unsubstituted aryloxy group, a substituted or unsubstituted amino group, a halogen atom, a cyan group, or a substituted or unsubstituted silyl group, and R^{f} and R^{h} are hydrogen atoms. In another preferred embodiment of the present invention, R^{e} and R^{g} each are independently a substituted or unsubstituted amino group, and R^{f} and R^{h} are hydrogen atoms. R^{c}, R^{f}, R^{g} and R^{h} can be all hydrogen atoms.

In another preferred embodiment of the present invention, the fourth organic compound is a compound represented by the following general formula (17).

HetAr¹—L²¹—HetAr² General Formula (17)

In the general formula (17), HetAr¹ and HetAr² each independently represent a group represented by the following general formula (18), and at least one of them is a group represented by the general formula (18) substituted with the general formula (19). L²¹ represents a linking group, for which reference can be made to the description and the preferred range of L in the general formula (3) mentioned hereinabove. In one preferred embodiment of the present invention, L²¹ in the general formula (17) is an unsubstituted arylene group having 6 to 16 carbon atoms.

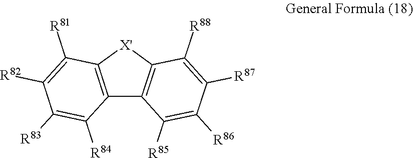

In the general formula (18), X¹ represents an oxygen atom, a sulfur atom or N—R⁸⁹. One of R⁸¹ to R⁸⁹ bonds to L and the remaining R⁸¹ to R⁸⁹ each are independently a hydrogen atom or a substituent. Regarding the description and the preferred range of the substituent, reference can be made to the description and the preferred range of the substituent in the general formula (7) mentioned hereinabove. Regarding the description and the preferred range of the substituent, reference can also be made to the description and the preferred range of R^{c} and R^{d} in the general formula (15) mentioned hereinabove, in which, however, a hydrogen atom is excluded. R⁸¹ and R⁸², R⁸² and R⁸³, R⁸³ and R⁸⁴, R⁸⁵ and R⁸⁶, R⁸⁶ and R⁸⁷, and R⁸⁷ and R⁸⁸ each can bond to each other to form a cyclic structure.

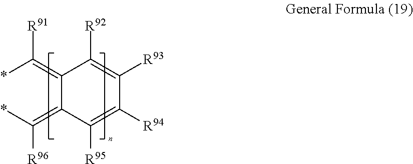

In the general formula (19), n represents an integer of 0 or more, and R⁹¹ to R⁹⁶ each independently represent a hydrogen atom or a substituent. Regarding the description and the preferred range of the substituent, reference can be made to the description and the preferred range of the substituent in the general formula (7) mentioned hereinabove. Regarding the description and the preferred range of the substituent, reference can also be made to the description and the preferred range of R^{c} and R^{d} in the general formula (15) mentioned hereinabove, in which, however, a hydrogen atom is excluded. n is preferably 0 to 3, and can be, for example, 0 or can be 1. * indicates a bonding position to the carbon atom that constitutes the ring skeleton of the ring in the general formula (18).

Of the compounds represented by the general formula (17), the compound represented by the following general formula (20) is especially preferably employed here.

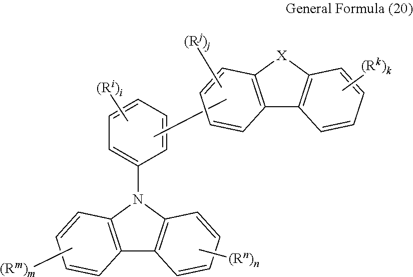

In the general formula (20), X represents an oxygen atom, a sulfur atom or N—R^{p}, Rⁱ, R^{j}, R^{k}, R^{m}, Rⁿ and R^{p} each independently represent a substituent. Regarding the description and the preferred range of the substituent, reference can be made to the description and the preferred range of the substituent in the general formula (18) mentioned hereinabove. i, k, m and n in the general formula (20) each independently represent an integer of any of 0 to 4. j represents an integer of any of 0 to 3. i, j, k, m and n can be each independently selected within a range of, for example, 0 to 2, or can be selected within a range of 0 to 1, or all can be 0. In one preferred embodiment of the present invention, X represents an oxygen atom. In another preferred embodiment of the present invention, X represents an oxygen atom or a sulfur atom, and X bonds to the benzene ring in the center of the general formula (20) via the 2-position of the X-containing dibenzofuran ring or dibenzothiophene ring. In another preferred embodiment of the present invention, the x-containing tricyclic structure bonds to the central benzene ring via the meta-position of the 9-carbazolyl group.

In one preferred embodiment of the present invention, the fourth organic compound is a symmetric compound.

Two or more kinds of the fourth organic compounds can be used as combined so far as they satisfy the requirement (a) and the requirement (b).

Hereinunder shown are preferred compounds usable as the fourth organic compound.

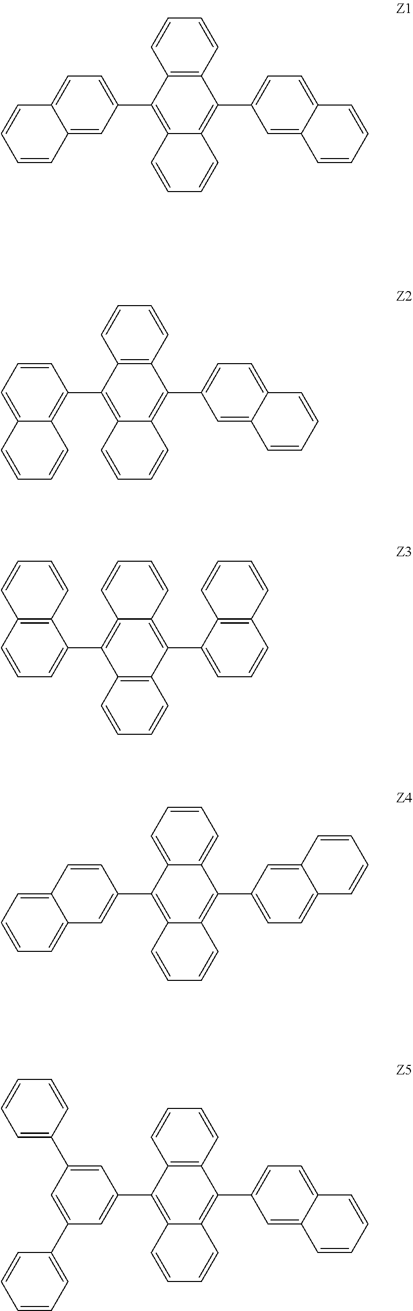

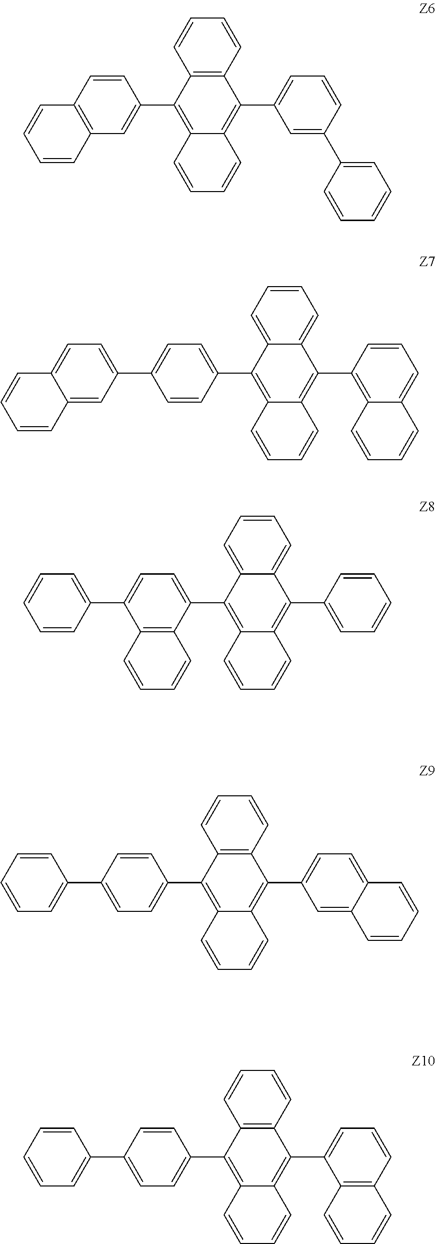

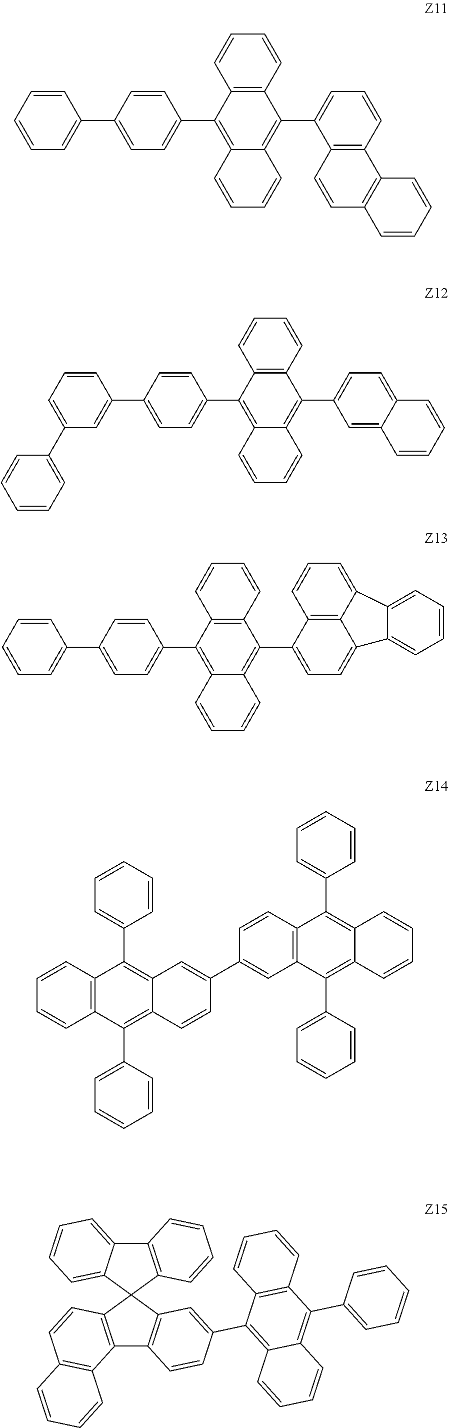

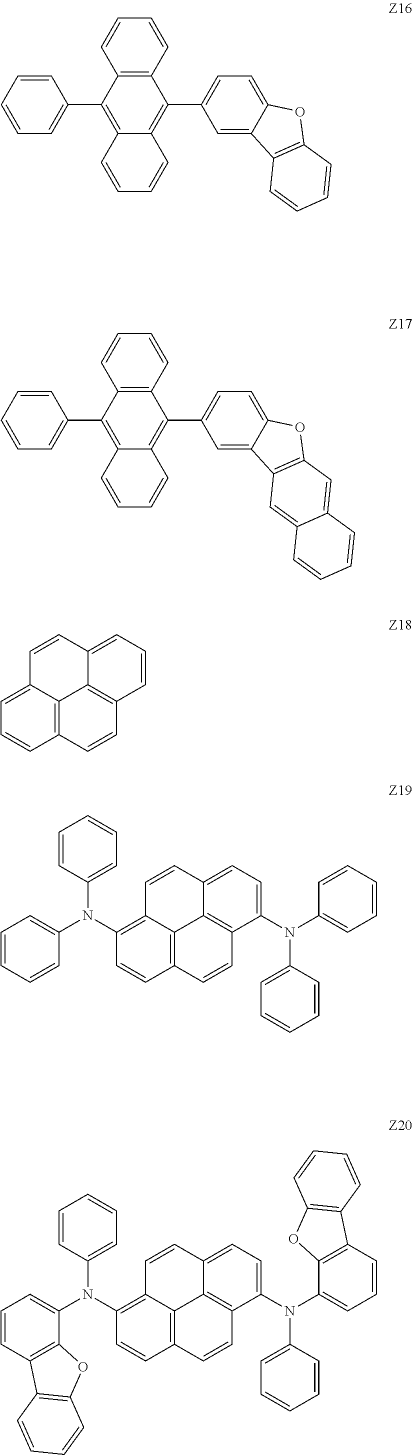

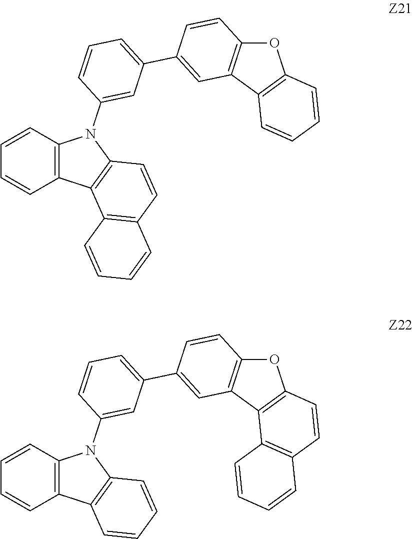 [SMILES: c1cc(-c2ccc3oc4ccccc4c3c2)cc(-n2c3ccccc3c3c4ccccc4ccc32)c1 ; c1cc(-c2ccc3oc4ccc5ccccc5c4c3c2)cc(-n2c3ccccc3c3ccccc32)c1]

### (Light Emitting Layer)

The light emitting layer in the organic light emitting device of the present

invention contains the first organic compound, the second organic compound, the third organic compound and the fourth organic compound satisfying the requirement (a) and the requirement (b). The light emitting layer can be so configured that it does not contain a compound and a metal element that donate or accept charge and energy, except the first organic compound, the second organic compound, the third organic compound and the fourth organic compound. Also the light emitting layer can be so configured as to be composed of only the first organic compound, the second organic compound, the third organic compound and the fourth organic compound. Further, the light emitting layer can be composed of compounds alone each formed of atoms selected from the group consisting of a carbon atom, a hydrogen atom, a nitrogen atom, a boron atom, an oxygen atom and a sulfur atom. For example, the light emitting layer can be composed of compounds alone each formed of atoms selected from the group consisting of a carbon atom, a hydrogen atom, a nitrogen atom, a boron atom and an oxygen atom. For example, the light emitting layer can be composed of compounds alone each formed of atoms selected from the group consisting of a carbon atom, a hydrogen atom, a nitrogen atom, a boron atom and a sulfur atom. For example, the light emitting layer can be composed of compounds alone each formed of atoms selected from the group consisting of a carbon atom, a hydrogen atom, a nitrogen atom and a boron atom. For example, the light emitting layer can be composed of compounds alone each formed of atoms selected from the group consisting of a carbon atom, a hydrogen atom, a nitrogen atom, an oxygen atom and a sulfur atom. For example, the light emitting layer can be composed of compounds alone each formed of atoms selected from the group consisting of a carbon atom, a hydrogen atom and a nitrogen atom. Or the first organic compound, the second organic compound and the fourth organic compound contained in the light emitting layer can be each independently a compound formed of atoms selected from the group consisting of a carbon atom, a hydrogen atom, a nitrogen atom, an oxygen atom and a sulfur atom. For example, the first organic compound, the second organic compound and the fourth organic compound can be each independently a compound formed of atoms selected from the group consisting of a carbon atom, a hydrogen atom, a nitrogen atom and an oxygen atom. For example, the first organic compound, the second organic compound and the fourth organic compound can be each independently a compound formed of atoms selected from the group consisting of a carbon atom, a hydrogen atom, a nitrogen atom and a sulfur atom. For example, the first organic compound, the second organic compound and the fourth organic compound can be each independently a compound formed of atoms selected from the group consisting of a carbon atom, a hydrogen atom and a nitrogen atom.

The light emitting layer can be formed by co-evaporation of the first organic compound, the second organic compound, the third organic compound and the fourth organic compound, or can be formed by coating method that uses a solution prepared by dissolving the first organic compound, the second organic compound, the third organic compound and the fourth organic compound. In the case where the light emitting layer is formed by co-evaporation, two or more of the first organic compound, the second organic compound, the third organic compound and the fourth organic compound are previously mixed and put into a crucible or the like to be an evaporation source, and using the evaporation source, the light emitting layer can be formed by co-evaporation. For example, the second organic compound, the third organic compound and the fourth organic compound are previously mixed to form one evaporation source, and using the evaporation source and an evaporation source of the first organic compound, the light emitting layer can be formed by co-evaporation.

### (Layer Configuration of Organic Light Emitting Device)

By forming a light emitting layer that contains the first organic compound, the second organic compound, the third organic compound and the fourth organic compound satisfying the requirement (a) and the requirement (b), there can be provided an excellent organic light emitting device such as an organic photoluminescent device (organic PL device) and an organic electroluminescent device (organic EL device).

The thickness of the light emitting layer can be 1 to 15 nm, or can be 2 to 10 nm or can be 3 to 7 nm.

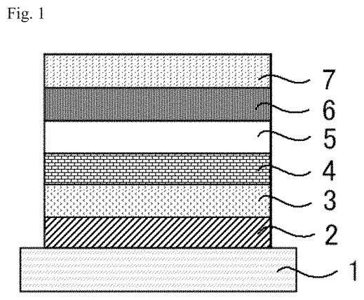

The organic photoluminescent device is so configured as to have at least a light emitting layer formed on a substrate. The organic electroluminescent device is so configured as to have at least an anode, a cathode and an organic layer formed between the anode and the cathode. The organic layer contains at least a light emitting layer, and can be composed of a light emitting layer, or can have at least one other organic layer in addition to the light emitting layer. Such other organic layers include hole transporting layer, a hole injection layer, an electron barrier layer, a hole barrier layer, an electron injection layer, an electron transporting layer and an exciton barrier layer. The hole transporting layer can also be a hole injection and transporting layer having a hole injection function, and the electron transporting layer can also be an electron injection transporting layer having an electron injection function. A specific configuration example of an organic electroluminescent device is shown in FIG. 1. In FIG. 1, 1 is a substrate, 2 is an anode, 3 is a hole injection layer, 4 is a hole transporting layer, 5 is a light emitting layer, 6 is an electron transporting layer, and 7 is a cathode.

In the case where the organic light emitting device of the invention is a multi-wavelength emission-type organic light emitting device, the device can be so designed that shortest wavelength emission contains delayed fluorescence. The device can be so designed that shortest wavelength emission does not contain delayed fluorescence.

In the following, the constituent members and the other layers than the light-emitting layer of the organic electroluminescent device are described.

### Substrate:

In some embodiments, the organic electroluminescent device of the invention is supported by a substrate, wherein the substrate is not particularly limited and may be any of those that have been commonly used in an organic electroluminescent device, for example those formed of glass, transparent plastics, quartz and silicon.

Anode In some embodiments, the anode of the organic electroluminescent device is made of a metal, an alloy, an electroconductive compound, or a combination thereof. In some embodiments, the metal, alloy, or electroconductive compound has a large work function (4 eV or more). In some embodiments, the metal is Au. In some embodiments, the electroconductive transparent material is selected from Cu, indium tin oxide (ITO), SnO₂, and ZnO. In some embodiments, an amorphous material capable of forming a transparent electroconductive film, such as IDIXO (In₂O₃—ZnO), is be used. In some embodiments, the anode is a thin film. In some embodiments the thin film is made by vapor deposition or sputtering. In some embodiments, the film is patterned by a photolithography method. In some embodiments, where the pattern may not require high accuracy (for example, approximately 100 μm or more), the pattern may be formed with a mask having a desired shape on vapor deposition or sputtering of the electrode material. In some embodiments, when a material can be applied as a coating, such as an organic electroconductive compound, a wet film forming method, such as a printing method and a coating method is used. In some embodiments, when the emitted light goes through the anode, the anode has a transmittance of more than 10%, and the anode has a sheet resistance of several hundred Ohm per square or less. In some embodiments, the thickness of the anode is from 10 to 1,000 nm. In some embodiments, the thickness of the anode is from 10 to 200 nm. In some embodiments, the thickness of the anode varies depending on the material used.

### Cathode

In some embodiments, the cathode is made of an electrode material a metal having a small work function (4 eV or less) (referred to as an electron injection metal), an alloy, an electroconductive compound, or a combination thereof. In some embodiments, the electrode material is selected from sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. In some embodiments, a mixture of an electron injection metal and a second metal that is a stable metal having a larger work function than the electron injection metal is used. In some embodiments, the mixture is selected from a magnesium-silver mixture, a magnesium-aluminum mixture, a magnesium-indium mixture, an aluminum-aluminum oxide (Al₂O₃) mixture, a lithium-aluminum mixture, and aluminum. In some embodiments, the mixture increases the electron injection property and the durability against oxidation. In some embodiments, the cathode is produced by forming the electrode material into a thin film by vapor deposition or sputtering. In some embodiments, the cathode has a sheet resistance of several hundred Ohm per square or less. In some embodiments, the thickness of the cathode ranges from 10 nm to 5 μm. In some embodiments, the thickness of the cathode ranges from 50 to 200 nm. In some embodiments, for transmitting the emitted light, any one of the anode and the cathode of the organic electroluminescent device is transparent or translucent. In some embodiments, the transparent or translucent electroluminescent devices enhances the light emission luminance.

In some embodiments, the cathode is formed with an electroconductive transparent material, as described for the anode, to form a transparent or translucent cathode. In some embodiments, a device comprises an anode and a cathode, both being transparent or translucent.

### Injection Layer

An injection layer is a layer between the electrode and the organic layer. In some embodiments, the injection layer decreases the driving voltage and enhances the light emission luminance. In some embodiments the injection layer includes a hole injection layer and an electron injection layer. The injection layer can be positioned between the anode and the light-emitting layer or the hole transporting layer, and between the cathode and the light-emitting layer or the electron transporting layer. In some embodiments, an injection layer is present. In some embodiments, no injection layer is present.

Preferred compound examples for use as a hole injection material are shown below.

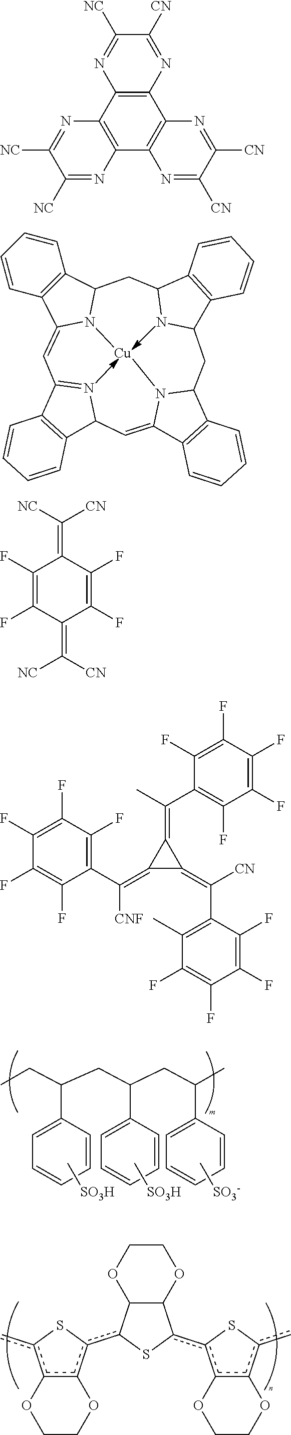

Next, preferred compound examples for use as an electron injection material are shown below.

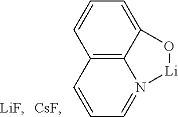

### Barrier Layer

A barrier layer is a layer capable of inhibiting charges (electrons or holes) and/or excitons present in the light-emitting layer from being diffused outside the light-emitting layer. In some embodiments, the electron barrier layer is between the light-emitting layer and the hole transporting layer, and inhibits electrons from passing through the light-emitting layer toward the hole transporting layer. In some embodiments, the hole barrier layer is between the light-emitting layer and the electron transporting layer, and inhibits holes from passing through the light-emitting layer toward the electron transporting layer. In some embodiments, the barrier layer inhibits excitons from being diffused outside the light-emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### Hole Barrier Layer

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light-emitting layer. The material for the hole barrier layer may be the same materials as the ones described for the electron transporting layer.

Preferred compound examples for use for the hole barrier layer are shown below.

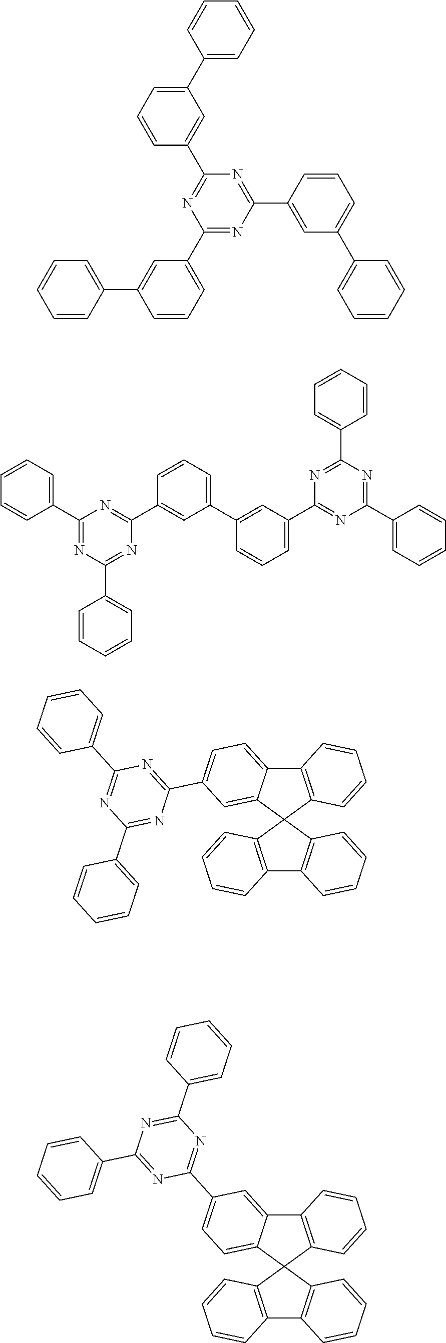

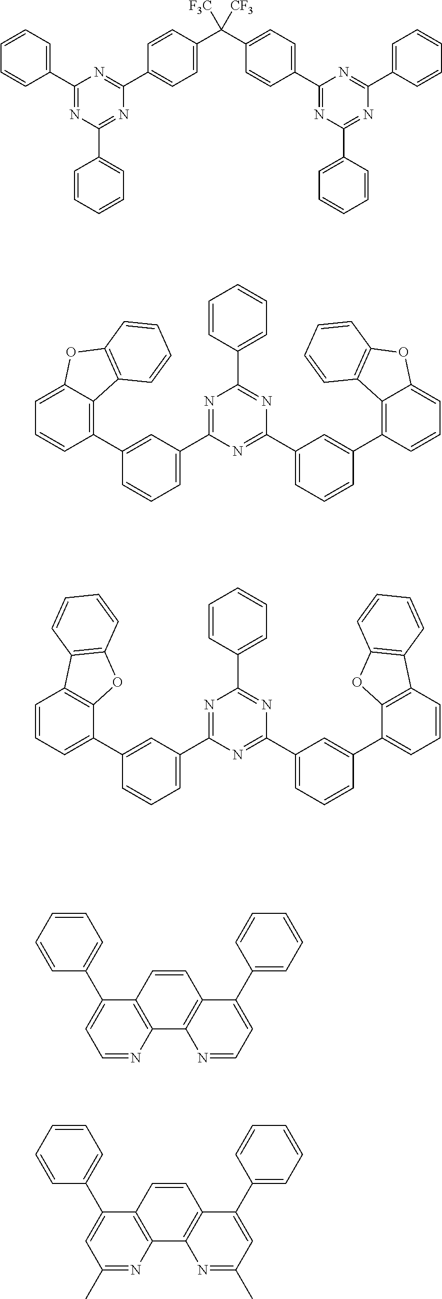 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2nc(-c3cccc(-c4cccc5oc6ccccc6c45)c3)nc(-c3cccc(-c4cccc5oc6ccccc6c45)c3)n2)cc1 ; c1ccc(-c2nc(-c3cccc(-c4cccc5c4oc4ccccc45)c3)nc(-c3cccc(-c4cccc5c4oc4ccccc45)c3)n2)cc1 ; c1ccc(-c2ccnc3c2ccc2c(-c4ccccc4)ccnc23)cc1 ; Cc1cc(-c2ccccc2)c2ccc3c(-c4ccccc4)cc(C)nc3c2n1]

### Electron Barrier Layer

As electron barrier layer transports holes. In some embodiments, the electron barrier layer inhibits electrons from reaching the hole transporting layer while transporting holes. In some embodiments, the electron barrier layer enhances the recombination probability of electrons and holes in the light-emitting layer.

Preferred compound examples for use as the electron barrier material are shown below.

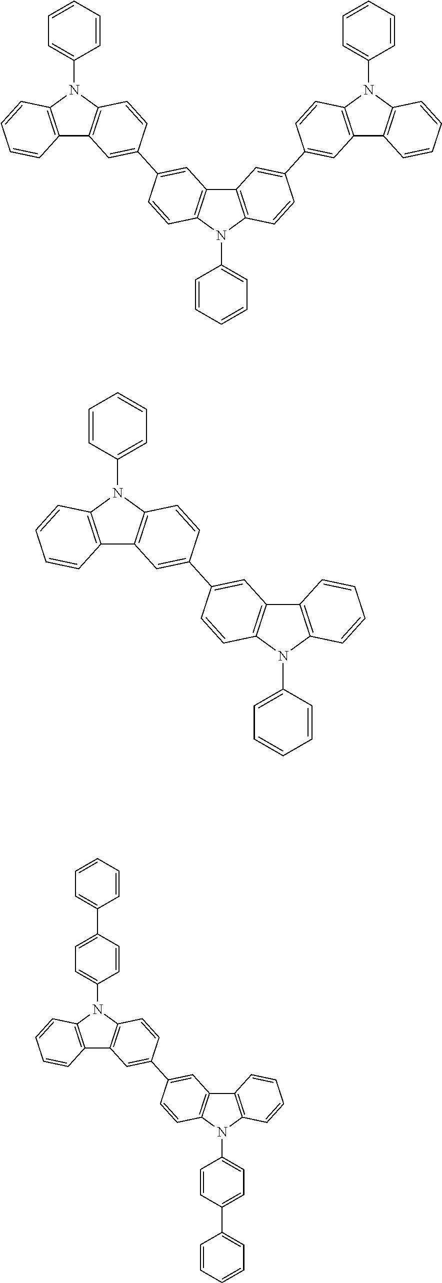 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

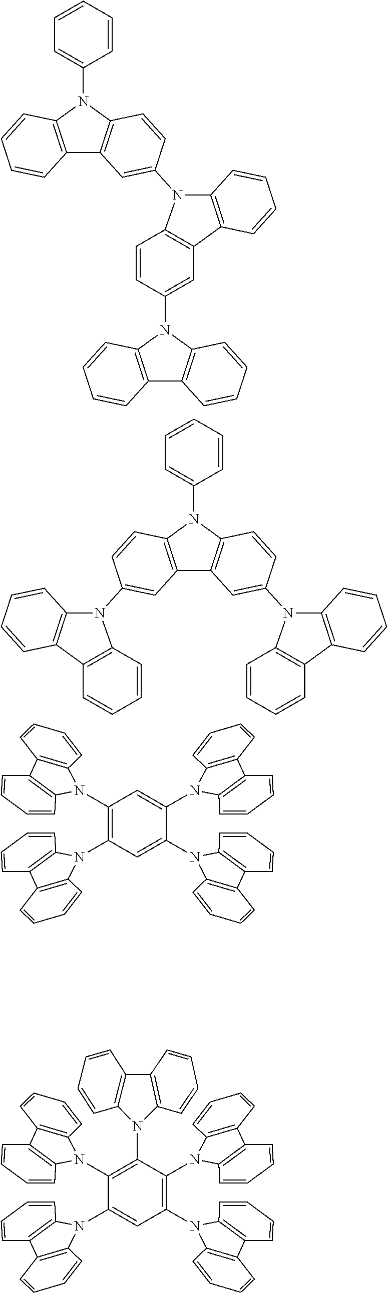

### Exciton Barrier Layer

An exciton barrier layer inhibits excitons generated through recombination of holes and electrons in the light-emitting layer from being diffused to the charge transporting layer. In some embodiments, the exciton barrier layer enables effective confinement of excitons in the light-emitting layer. In some embodiments, the light emission efficiency of the device is enhanced. In some embodiments, the exciton barrier layer is adjacent to the light-emitting layer on any of the side of the anode and the side of the cathode, and on both the sides. In some embodiments, where the exciton barrier layer is on the side of the anode, the layer can be between the hole transporting layer and the light-emitting layer and adjacent to the light-emitting layer. In some embodiments, where the exciton barrier layer is on the side of the cathode, the layer can be between the light-emitting layer and the cathode and adjacent to the light-emitting layer. In some embodiments, a hole injection layer, an electron barrier layer, or a similar layer is between the anode and the exciton barrier layer that is adjacent to the light-emitting layer on the side of the anode. In some embodiments, a hole injection layer, an electron barrier layer, a hole barrier layer, or a similar layer is between the cathode and the exciton barrier layer that is adjacent to the light-emitting layer on the side of the cathode. In some embodiments, the exciton barrier layer comprises excited singlet energy and excited triplet energy, at least one of which is higher than the excited singlet energy and the excited triplet energy of the light-emitting material, respectively.

### Hole Transporting Layer

The hole transporting layer comprises a hole transporting material. In some embodiments, the hole transporting layer is a single layer. In some embodiments, the hole transporting layer comprises a plurality layers.

In some embodiments, the hole transporting material has one of injection or transporting property of holes and barrier property of electrons. In some embodiments, the hole transporting material is an organic material. In some embodiments, the hole transporting material is an inorganic material. Examples of known hole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof. In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

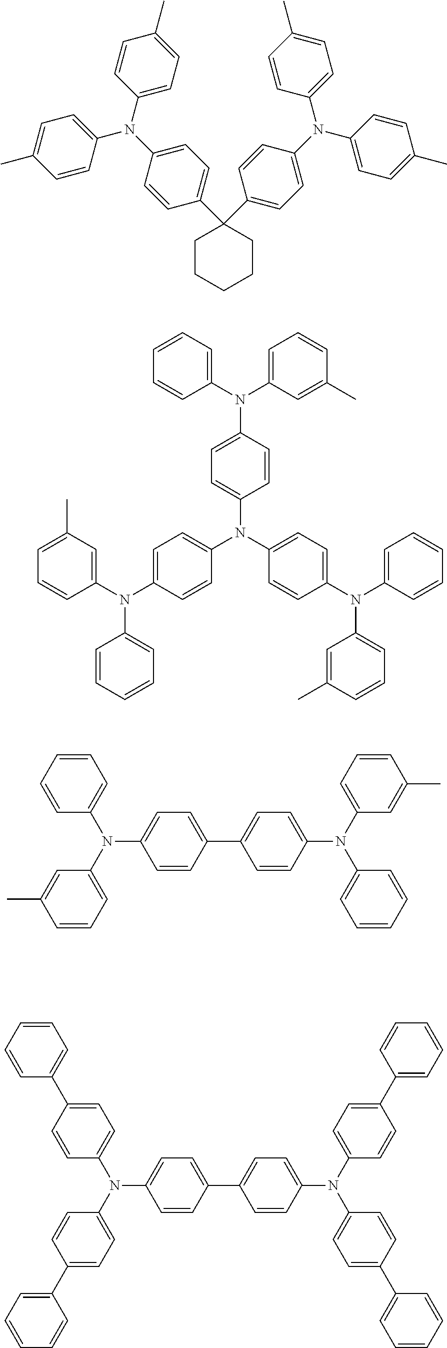

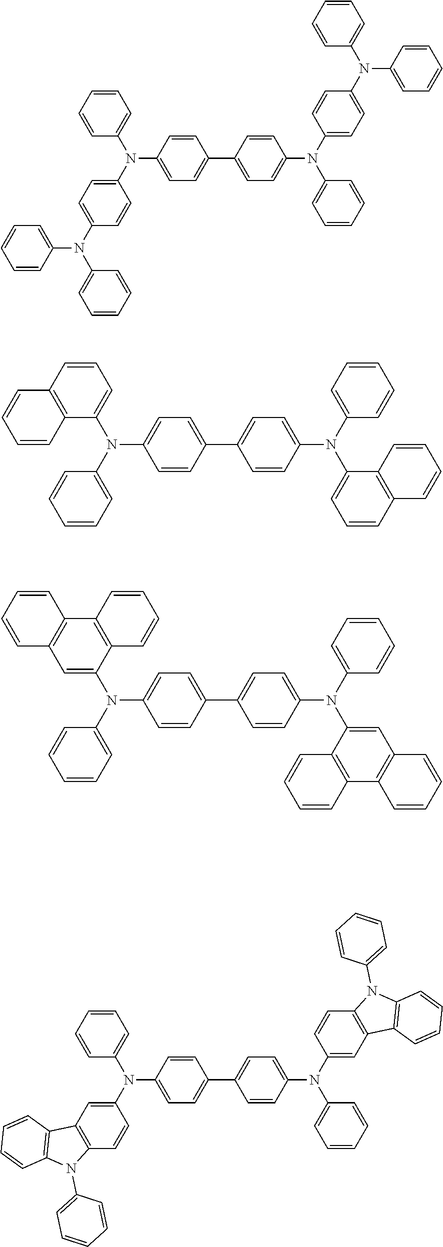 [SMILES: c1ccc(N(c2ccccc2)c2ccc(N(c3ccccc3)c3ccc(-c4ccc(N(c5ccccc5)c5ccc(N(c6ccccc6)c6ccccc6)cc5)cc4)cc3)cc2)cc1 ; c1ccc(N(c2ccc(-c3ccc(N(c4ccccc4)c4cccc5ccccc45)cc3)cc2)c2cccc3ccccc23)cc1 ; c1ccc(N(c2ccc(-c3ccc(N(c4ccccc4)c4cc5ccccc5c5ccccc45)cc3)cc2)c2cc3ccccc3c3ccccc23)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

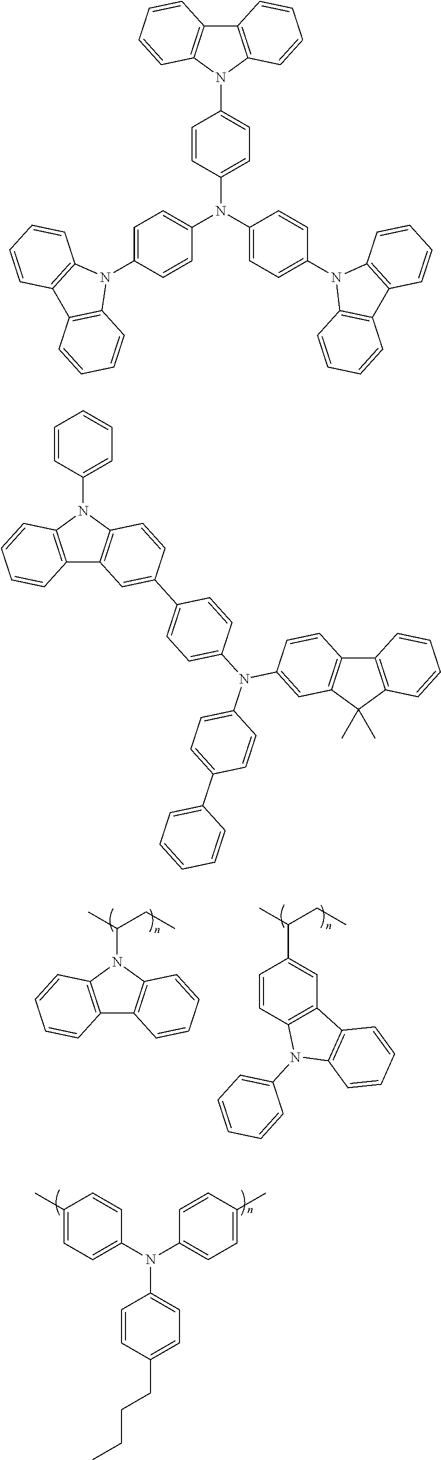

### Electron Transporting Layer

The electron transporting layer comprises an electron transporting material. In some embodiments, the electron transporting layer is a single layer. In some embodiments, the electron transporting layer comprises a plurality of layer.

In some embodiments, the electron transporting material needs only to have a function of transporting electrons, which are injected from the cathode, to the light-emitting layer. In some embodiments, the electron transporting material also function as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an azole derivative, an azine derivative, an oxadiazole derivative, or a combination thereof, or a polymer thereof. In some embodiments, the electron transporting material is a thiadiazole derivative, or a quinoxaline derivative. In some embodiments, the electron transporting material is a polymer material. Preferred compound examples for use as the electron transporting material are shown below.

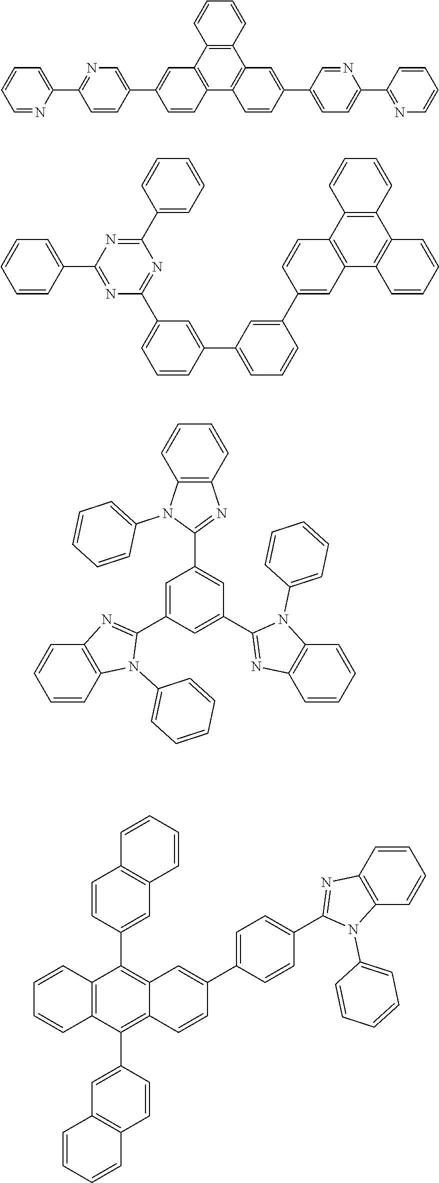

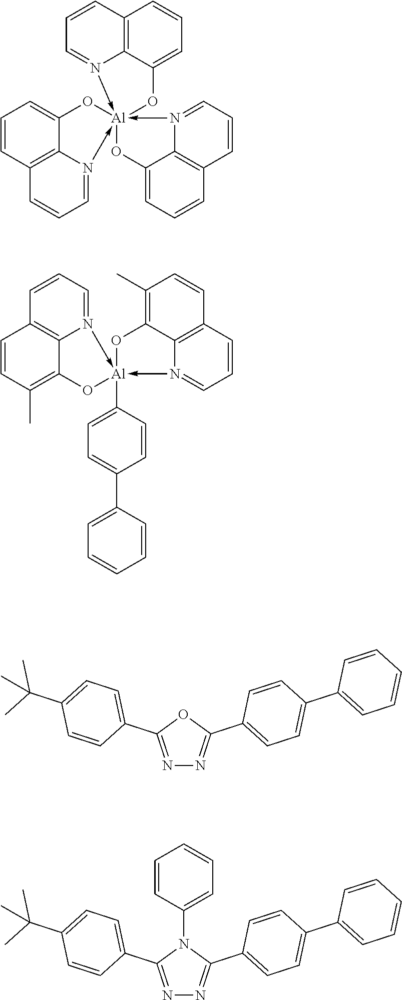

Hereinunder compound examples preferred as a material that can be added to the organic layers are shown. For example, these can be added as a stabilization material.

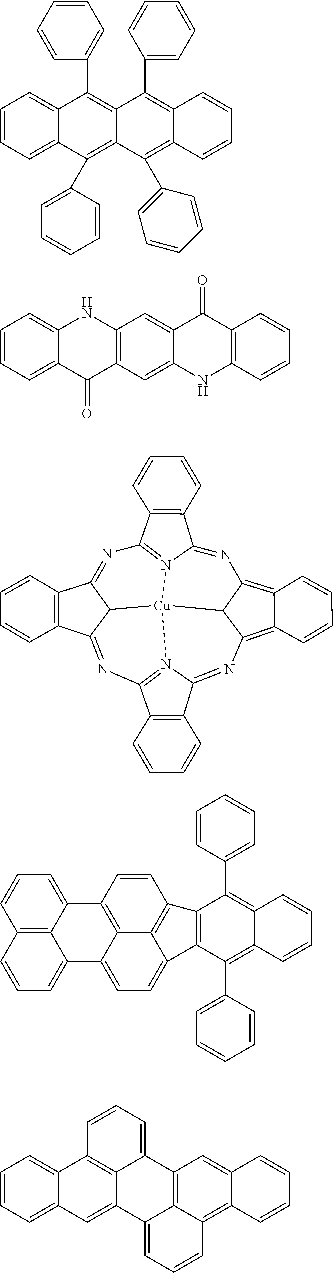

Preferred materials for use in the organic electroluminescent device are specifically shown. However, the materials usable in the invention should not be limitatively interpreted by the following exemplary compounds. Compounds that are exemplified as materials having a specific function can also be used as materials having any other function.

### Devices

In some embodiments, an light emitting layer is incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as a OLEDs or photovoltaic devices. In some embodiments, the composition may be useful in facilitating charge transfer or energy transfer within a device and/or as a hole-transport material. The device may be, for example, an organic light-emitting diode (OLED), an organic integrated circuit (0-1C), an organic field-effect transistor (0-FET), an organic thin-film transistor (O-TFT), an organic light-emitting transistor (0-LET), an organic solar cell (0-SC), an organic optical detector, an organic photoreceptor, an organic field-quench device (0-FQD), a light-emitting electrochemical cell (LEC) or an organic laser diode (0-laser).

### Bulbs or Lamps

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB).

In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:

a circuit board having a first side with a mounting surface and an opposing second side, and defining at least one aperture;

at least one OLED on the mounting surface, the at least one OLED configured to emanate light, comprising:
an anode, a cathode, and at least one organic layer comprising a light emitting layer between the anode and the cathode;

a housing for the circuit board; and

at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### Displays or Screens

In some embodiments, the compounds of the invention can be used in a screen or a display. In some embodiments, the compounds of the invention are deposited onto a substrate using a process including, but not limited to, vacuum evaporation, deposition, vapor deposition, or chemical vapor deposition (CVD). In some embodiments, the substrate is a photoplate structure useful in a two-sided etch provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point the entire pixel area is subjected to a similar etch rate but the depths are varying depending on the halftone pattern. Varying the size and spacing of the halftone pattern allows etching to be inhibited at different rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### Methods of Manufacturing Devices Using the Disclosed Compounds

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light-emitting layer, a counter electrode, and an encapsulation layer, and then is cut from the mother panel.

In another aspect, provided herein is a method of manufacturing an organic light-emitting diode (OLED) display, the method comprising:

forming a barrier layer on a base substrate of a mother panel:

forming a plurality of display units in units of cell panels on the barrier layer;

forming an encapsulation layer on each of the display units of the cell panels;

applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light-emitting layer, a gate electrode, and a source/drain electrode. Each of the plurality of display units may include a thin film transistor (TFT) layer, a planarization film formed on the TFT layer, and a light-emitting unit formed on the planarization film, wherein the organic film applied to the interface portion is formed of a same material as a material of the planarization film and is formed at a same time as the planarization film is formed. In some embodiments, a light-emitting unit is connected to the TFT layer with a passivation layer and a planarization film therebetween and an encapsulation layer that covers and protects the light-emitting unit. In some embodiments of the method of manufacturing, the organic film contacts neither the display units nor the encapsulation layer.

Each of the organic film and the planarization film may include any one of polyimide and acryl. In some embodiments, the barrier layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light-emitting layer includes a pixel electrode, a counter electrode, and an organic light-emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light-emitting layer emits light, thereby forming an image. Hereinafter, an image forming unit including the TFT layer and the light-emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light-emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including: a barrier layer that is formed on a base substrate: a display unit that is formed on the barrier layer: an encapsulation layer that is formed on the display unit: and an organic film that is applied to an edge portion of the barrier layer.

### (Design Method for Light Emitting Composition)

The present invention also proposes a method for designing the composition of the present invention that has a long emission lifetime and is excellent in stability.

The design method for the light emitting composition of the present invention includes the following steps 1 to 3.

[Step 1] evaluating an emission efficiency and a lifetime of a composition containing a first organic compound, a second organic compound of a delayed fluorescent material, a third organic compound and a fourth organic compound and satisfying the requirements (a) and (b),

[Step 2] carrying out at least one time evaluating an emission efficiency and a lifetime of a composition in which at least one of the first organic compound, the second organic compound of a delayed fluorescent material, the third organic compound and the fourth organic compound has been replaced within a range satisfying the requirements (a) and (b),

[Step 3] selecting a best combination of the results of the evaluated emission efficiency and lifetime.

Evaluation of the emission efficiency and the lifetime can be carried out by actually emitting a light emitting composition, or can be carried out by calculation. In addition, evaluation can also be carried out by actually emitting a light emitting composition combined with a calculation method. Preferably, evaluation is carried out from a comprehensive viewpoint using a high level of practicality as an index. In the design method for the light emitting composition of the present invention, it is necessary to select and replace the first organic compound, the second organic compound, the third organic compound and the fourth organic compound within a range satisfying the requirement (a) and the requirement (b). Also it is necessary to select and replace the second organic compound from a delayed fluorescent material. For the compound replacement in the step 2, preferably, the compound is replaced to another one capable of attaining a more excellent evaluation. The step 2 can be carried out, for example, 10 times or more, 100 times or more, 1000 times or more, or 10000 times or more.

The design method for the light emitting composition of the present invention can be stored as a program and can be used as such. The program can be stored on a recording medium and can be transmitted and received by an electronic means.

### EXAMPLES

The features of the present invention will be described more specifically with reference to Examples given below. The materials, processes, procedures and the like shown below may be appropriately modified unless they deviate from the substance of the invention. Accordingly, the scope of the invention is not construed as being limited to the specific examples shown below. Hereinunder the light emission characteristics were evaluated using a source meter (available from Keithley Instruments Corporation: 2400 series), a semiconductor parameter analyzer (available from Agilent Corporation, E5273A), an optical power meter device (available from Newport Corporation, 1930C), an optical spectroscope (available from Ocean Optics Corporation, USB2000), a spectroradiometer (available from Topcon Corporation, SR-3), and a streak camera (available from Hamamatsu Photonics K.K., Model C4334). The lowest excited singlet energy E_{S1} and the lowest excited triplet energy E_{T1} of the compounds used in the following Examples and Comparative Examples are as shown in the following Table.

TABLE 1

| | | E_{S1} (eV) | E_{T1} (eV) |
|---|---|---|---|
| First Organic Compound | Compound H1 | 3.54 | 3.06 |
| First Organic Compound | Compound T13 | 2.78 | 2.66 |
| First Organic Compound | Compound E1 | 2.72 | 2.59 |
| First Organic Compound | Compound Z1 | 2.90 | 2.13 |

### Example 1

On a glass substrate having, as formed thereon, an anode of indium tin oxide (ITO) having a thickness of 100 nm, thin films were laminated at a vacuum degree of 1×10⁻⁶ Pa according to a vacuum evaporation method. First, HATCN was deposited on ITO at a thickness of 10 nm, then NPD was deposited thereon at a thickness of 30 nm. Further thereon, TrisPCz was deposited at a thickness of 10 nm. Next, the compound H1 was formed at a thickness of 5 nm. Further, the compound H1 (68.5% by weight), the compound T13 (30% by weight), the compound E1 (0.5% by weight) and the compound Z1 (1% by weight) were co-evaporated from different evaporation sources to form a light emitting layer having a thickness of 30 nm. Next, SF3TRZ was formed at a thickness of 10 nm as a hole barrier layer. Subsequently, SF3TRZ and Liq were co-evaporated from different evaporation sources to form a layer having a thickness of 30 nm to be an electron transporting layer. At that time, SF3TRZ/Liq (by weight) was 7/3. Further, Liq was formed at a thickness of 2 nm, and then aluminum (Al) was deposited at a thickness of 100 nm to form a cathode. According to this process, an organic electroluminescent device of Example 1 was produced.

### Example 2

An organic electroluminescent device of Example 2 was produced according to the same process as in Example 1 except that the concentration in the light emitting layer was changed to the compound H1 (64.5% by weight), the compound T13 (30% by weight), the compound E1 (0.5% by weight) and the compound Z1 (5% by weight).

### Example 2, Comparative Examples 1 to 2

Organic electroluminescent devices of Example 2, Comparative Example 1 and Comparative Example 2 were produced according to the same process as in Example 1, except that the concentration in the light emitting layer was changed as in the following Table 2.

TABLE 2

| | Concentration (wt %) | | | |
|---|---|---|---|---|
| | Compound | Compound | Compound | Compound |
| | H1 | T13 | E1 | Z1 |
| Comparative | 0.0 | 30 | 0.5 | 70 |
| Example 1 | | | | |
| Comparative | 70.0 | 30 | 0.5 | 0 |
| Example 2 | | | | |
| Example 1 | 68.5 | 30 | 0.5 | 1 |
| Example 2 | 64.5 | 30 | 0.5 | 5 |

The thus-produced organic electroluminescent devices were energized and were recognized to have emitted delayed fluorescence derived from the third organic compound E1 (all having a maximum emission wavelength of 471 nm). The organic electroluminescent device of Comparative Example 1 has a low external quantum efficiency, and therefore this was not evaluated for the other properties. On the other hand, LT95 of Comparative Example 2, Example 1 and Example 2 all having a significantly higher external quantum efficiency than Comparative Example 1 was measured at 2 mA/cm². As a result, it was confirmed that the lifetime of Example 1 was 2.83 times that of Comparative Example 2, and that the lifetime of Example 2 was 12.4 times that of Comparative Example 2. In addition, it was also confirmed that with increase in the concentration of the compound Z1, the lifetime increases more.

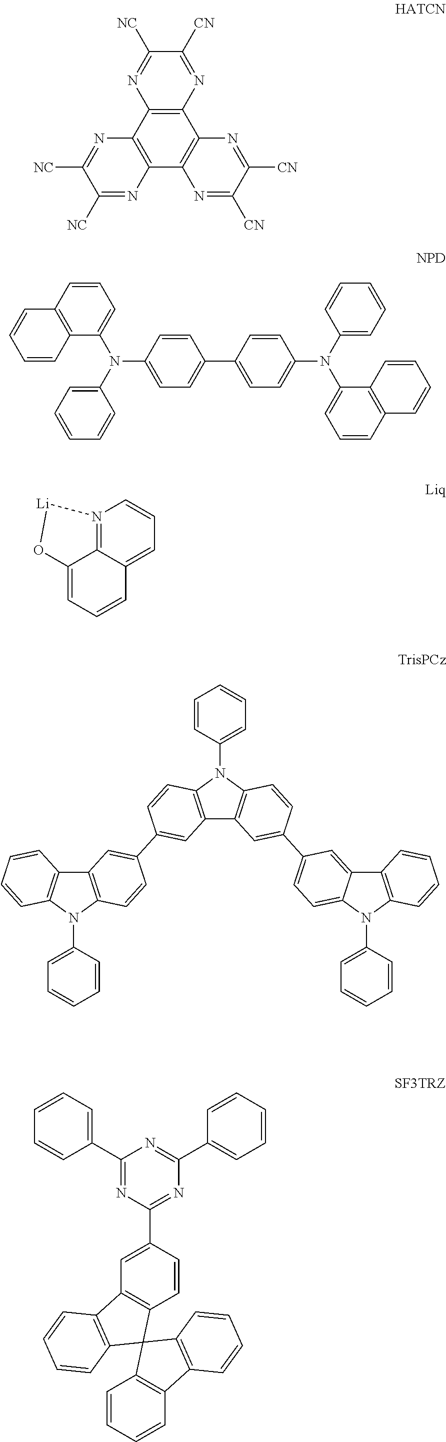

### INDUSTRIAL APPLICABILITY

According to the present invention, there can be provided an organic light emitting device having a long lifetime and stable. Accordingly, the industrial applicability of the present invention is great.

### REFERENCE SIGNS LIST

1 Substrate
2 Anode
3 Hole Injection Layer
4 Hole Transporting Layer
5 Light emitting Layer
6 Electron Transporting Layer
7 Cathode

1. An organic light emitting device having a light emitting layer that contains a first organic compound, a second organic compound, a third organic compound and a fourth organic compound satisfying the following requirements (a) and (b), wherein:
the second organic compound is a delayed fluorescent material,
maximum component of light emission from the organic light emitting device is light emission from the third organic compound:
Requirement (a): E_{S1}(1)>E_{S1}(4)>E_{S1}(2)>E_{S1}(3)
Requirement (b): E_{T1}(1)>E_{T1}(2)>E_{T1}(3)>E_{T1}(4)
wherein:
E_{S1}(1) represents a lowest excited singlet energy of the first organic compound,
E_{S1}(2) represents a lowest excited singlet energy of the second organic compound,
E_{S1}(3) represents a lowest excited singlet energy of the third organic compound,
E_{S1}(4) represents a lowest excited singlet energy of the fourth organic compound,
E_{T1}(I) represents a lowest excited triplet energy of the first organic compound,
E_{T1}(2) represents a lowest excited triplet energy of the second organic compound,
E_{T1}(3) represents a lowest excited triplet energy of the third organic compound,
E_{T1}(4) represents a lowest excited triplet energy of the fourth organic compound.

2. The organic light emitting device according to claim 1, further satisfying the following requirement (c):
Requirement (c): Conc(1)>Conc(2)>Conc(4)
wherein:
Conc(1) represents a concentration of the first organic compound in the light emitting layer,
Conc(2) represents a concentration of the second organic compound in the light emitting layer,
Conc(4) represents a concentration of the fourth organic compound in the light emitting layer.

3. The organic light emitting device according to claim 2, further satisfying the following requirement (c1):
Requirement (c1): Conc(1)>Conc(2)>Conc(4)>Conc(3)
wherein:
Conc(3) represents a concentration of the third organic compound in the light emitting layer.

4. The organic light emitting device according to claim 2, further satisfying the following requirement (d):
Requirement (d): Conc(2)/Conc(3)>5
wherein:
Conc(3) represents a concentration of the third organic compound in the light emitting layer.

5. The organic light emitting device according to claim 2, further satisfying the following requirement (e):
Requirement (e): Conc(4)/Conc(3)>1.5
wherein:
Conc(3) represents a concentration of the third organic compound in the light emitting layer.

6. The organic light emitting device according to claim 1, further satisfying the following requirement (f):
Requirement (f): Conc(4)<5 wt %
wherein:
Conc(4) represents a concentration of the fourth organic compound in the light emitting layer.

7. The organic light emitting device according to claim 1, further satisfying the following requirement (g):
Requirement (g): Conc(3)≤1 wt %
wherein:
Conc(3) represents a concentration of the third organic compound in the light emitting layer.

8. The organic light emitting device according to claim 1, wherein the second organic compound is such that an energy difference ΔE_{ST} between a lowest excited single state and a lowest excited triplet state at 77 K is 0.3 eV or less.

9. The organic light emitting device according to claim 1, wherein the third organic compound is such that an energy difference ΔE_{ST} between a lowest excited single state and a lowest excited triplet state at 77 K is 0.3 eV or less.

10. The organic light emitting device according to claim 1, wherein the light emitting layer is composed of a compound alone formed of atoms selected from the group consisting of a carbon atom, a hydrogen atom, a nitrogen atom, a boron atom, an oxygen atom and a sulfur atom.

11. The organic light emitting device according to claim 1, wherein the first organic compound, the second organic compound and the fourth organic compound each are independently a compound formed of atoms selected from the group consisting of a carbon atom, a hydrogen atom and a nitrogen atom.

12. The organic light emitting device according to claim 1, wherein the fourth organic compound is a compound composed of only a carbon atom and a hydrogen atom.

13. The organic light emitting device according to claim 1, wherein the second organic compound contains a cyanobenzene structure.

14. A method for designing a light emitting composition, comprising:
[1] evaluating an emission efficiency and a lifetime of a composition containing a first organic compound, a second organic compound of a delayed fluorescent material, a third organic compound and a fourth organic compound and satisfying the following requirements (a) and (b),
[2] carrying out at least one time evaluating an emission efficiency and a lifetime of a composition in which at least one of the first organic compound, the second organic compound of a delayed fluorescent material, the third organic compound and the fourth organic compound has been replaced within a range satisfying the following requirements (a) and (b), and
[3] selecting a best combination of the results of the evaluated emission efficiency and lifetime:
Requirement (a): E_{S1}(1)>E_{S1}(4)>E_{S1}(2)>E_{S1}(3)
Requirement (b): E_{T1}(1)>E_{T1}(2)>E_{T1}(3)>E_{T1}(4)
wherein:
E_{S1}(1) represents a lowest excited singlet energy of the first organic compound,
E_{S1}(2) represents a lowest excited singlet energy of the second organic compound,
E_{S1}(3) represents a lowest excited singlet energy of the third organic compound,
E_{S1}(4) represents a lowest excited singlet energy of the fourth organic compound,
E_{T1}(1) represents a lowest excited triplet energy of the first organic compound,
E_{T1}(2) represents a lowest excited triplet energy of the second organic compound,
E_{T1}(3) represents a lowest excited triplet energy of the third organic compound,
E_{T1}(4) represents a lowest excited triplet energy of the fourth organic compound.

15. A program of carrying out the method of claim 14.
